(19) United States
(12) Patent Application Publication
(10) Pub. No.: US 2026/0173392 A1
(43) Pub. Date: Jun. 18, 2026

(54) FERROELECTRIC NOR MEMORY ARCHITECTURES

(71) Applicant: Micron Technology, Inc., Boise, ID (US)

(72) Inventors: Lorenzo Fratin, Buccinasco (IT); Fabio Pellizzer, Boise, ID (US)

(21) Appl. No.: 19/393,397

(22) Filed: Nov. 18, 2025

Related U.S. Application Data
(60) Provisional application No. 63/734,561, filed on Dec. 16, 2024.

(51) Int. Cl. H10B 51/20; G11C 5/06; G11C 11/22; G11C 16/04; H10B 43/10; H10B 43/27; H10B 43/35; H10B 51/10; H10B 51/30; H10D 30/01; H10D 30/69

(52) U.S. Cl. CPC H10B 51/20; G11C 5/063; G11C 11/223; H10B 51/10; H10B 51/30; H10D 30/0415; H10D 30/701; G11C 16/0483; H10B 43/10; H10B 43/27; H10B 43/35; H10D 30/0413; H10D 30/693

(57) ABSTRACT

Methods, systems, and devices for ferroelectric NOR memory architectures are described. The ferroelectric NOR memory architecture may include a first pillar, a second pillar, and a third pillar positioned between the first and second pillars. The memory device may include multiple first memory cells positioned between a respective first word line and a first semiconductor material at a first side of the third pillar and multiple second memory cells positioned between a respective second word line and the first semiconductor material at a second side of the third pillar. The memory device may include multiple first portions and second portions of a second semiconductor material, where each first portion couples a respective first memory cell and a respective second memory cell to the first pillar, and where each second portion couples a respective first memory cell and a respective second memory cell to the second pillar.

### CROSS REFERENCE

The present Application for Patent claims priority to U.S. patent application Ser. No. 63/734,561 by Fratin et al., entitled “FERROELECTRIC NOR MEMORY ARCHITECTURES,” filed Dec. 16, 2024, which is assigned to the assignee hereof, and which is expressly incorporated by reference in its entirety herein.

### TECHNICAL FIELD

The following relates to one or more systems for memory, including ferroelectric NOR memory architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports ferroelectric NOR memory architectures in accordance with examples as disclosed herein.

FIGS. 2A and 2B show examples of an architecture that supports FeNOR memory architectures in accordance with examples as disclosed herein.

FIGS. 3A, 3B, 3C, 3D, 3E, and 3F show examples of fabrication operations that support FeNOR memory architectures in accordance with examples as disclosed herein.

FIGS. 4A, 4B, 4C, 4D, 4E, and 4F show examples of fabrication operations that support FeNOR memory architectures in accordance with examples as disclosed herein.

FIG. 5 shows a flowchart illustrating a method or methods that support FeNOR memory architectures in accordance with examples as disclosed herein.

### DETAILED DESCRIPTION

Some memory devices may implement a ferroelectric material in memory cells that are arranged Not-AND (NAND) architecture, such as a three-dimensional (3D) or vertical NAND architecture. For example, a ferroelectric material may be implemented in addition to a charge-trapping material, or instead of a charge trapping material, of a memory cell that alters (e.g., in accordance with a stored logic state, in accordance with a stored electric field) an activation voltage for a semiconductor channel associated with the memory cell (e.g., a channel associated with a stack or memory cells, a channel associated with a pillar of memory cells). In some examples, a memory device with such an implementation of a ferroelectric material may experience relatively faster programming (e.g., in accordance with a polarization change of the ferroelectric material, in accordance with a change in dipole polarization) or relatively lower power consumption (e.g., by reducing or avoiding electron transfer associated with a charge trapping material, with relatively lower write voltages) than a memory device with other implementations of charge-trapping materials. However, some implementations of ferroelectric material in a memory array may have other performance tradeoffs. For example, some implementations of a ferroelectric material in such architectures may be associated with relatively high read latency, a relatively high erase latency, or both (e.g., due to relatively low current in vertical channels of a 3D NAND array, due to a relatively high capacitance of planar word lines implemented in a 3D NAND array, or both).

In accordance with the techniques described herein, ferroelectric memory cells may be implemented in accordance with a Not-OR (NOR) architecture (e.g., a FeNOR (FeNOR) architecture, a 3D FeNOR architecture), in which each memory cell along a column of the NOR architecture may be connected with (e.g., between) vertical source lines and bit lines (e.g., also referred to as drain lines). For example, a memory array implementing a FeNOR architecture may include first pillars (e.g., conductive pillars, conductors, each associated with a first access line, such as a bit line or source line), second pillars (e.g., conductive pillars, conductors, each associated with a second access line, such as a bit line or drain line), and third pillars each positioned between respective first and second pillars. Each of the third pillars may include a first semiconductor material that extends along the third pillar (e.g., along a length direction, along a height direction). The memory array may also include multiple first memory cells (e.g., associated with first transistors including a ferroelectric material) along a given third pillar that are each positioned between a respective first word line and the first semiconductor material at a first side of the third pillar, and multiple second memory cells (e.g., associated with second transistors including a ferroelectric material) along the given third pillar that are each positioned between a respective second word line and the first semiconductor material at a second side of the third pillar. To form semiconductor channels associated with the first and second memory cells (e.g., between a first pillar and a second pillar), the memory device may include multiple portions of a second semiconductor material (e.g., having a different doping configuration than the first semiconductor material) between the first semiconductor material and each of the respective first and second pillars. Thus, an FeNOR memory array may include stacks of memory cells (e.g., along one or more sides of a given pillar of memory cells), which may be configured to support an improved balance of read latency, write latency, power consumption, and storage volatility compared with other implementations and architectures.

In addition to applicability in memory systems as described herein, techniques for FeNOR architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by providing for an increased quantity of memory cells (e.g., NOR memory cells) arranged in a pier and pillar architecture, which may decrease latency associated with read and programming operations, improve random access speeds, and reduce power consumption, among other benefits.

Features of the disclosure are illustrated and described in the context of memory devices and related circuitry. Features of the disclosure are further illustrated and described in the context of architectures, memory devices, and flowcharts.

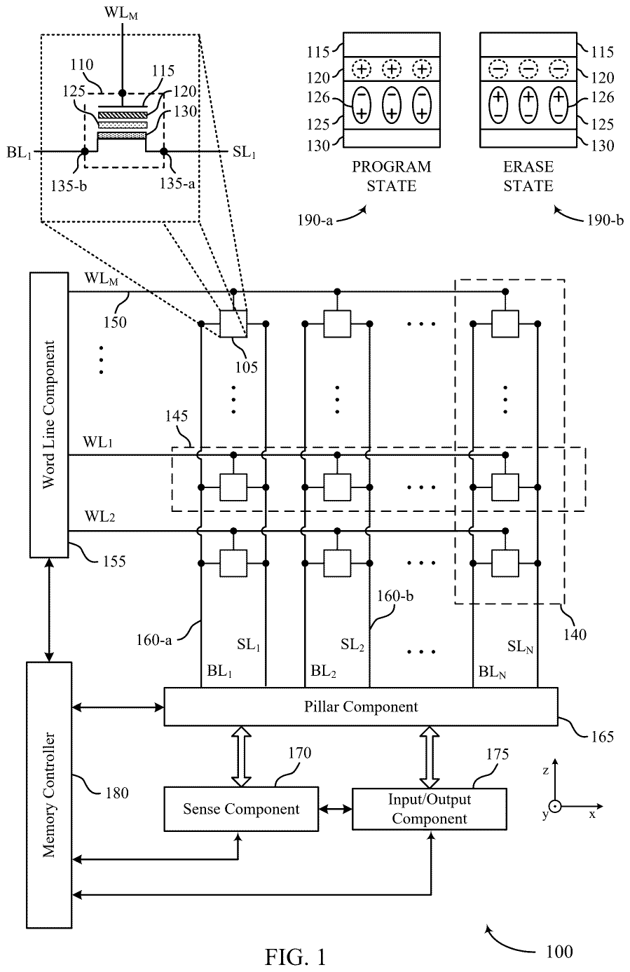

FIG. 1 shows an example of a memory device 100 that supports FeNOR memory architectures in accordance with examples as disclosed herein. The memory device 100 may be referred to as a memory die or an electronic memory apparatus, and include one or more arrays of memory cells 105. FIG. 1 is an illustrative representation of various components and features of the memory device 100. As such, the components and features of the memory device 100 are shown to illustrate functional relationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features. Aspects of the memory device 100 may be described with reference to an x-direction, a y-direction, and a z-direction of the illustrated coordinate system.

A memory device 100 may implement non-volatile memory cells that are based on ferroelectric properties of various materials, such as dopant-free hafnium oxide (HfOx) or hafnium zirconium oxide (HfZrOx), among other examples. Such memory cells may be referred to as ferroelectric field-effect transistor (Fe-FETs) memory cells and may, in some examples, be implemented in a NAND architecture (e.g., 3D NAND architecture) by replacing or combining a charge-trapping material in a gate dielectric stack with a ferroelectric material. Compared with a charge-trapping material, which may store an electric field based on electron transfer into or out of the charge-trapping material (e.g., by way of hot electron tunneling, by way of Fowler-Nordheim (FN) tunneling), a ferroelectric material may store an electric field by way of polarization (e.g., a dipole polarization, a polarization orientation, a dipole orientation, an electric field orientation, with or without an accompanying electron transfer) of the ferroelectric material, which may be associated with a switching mechanism of ferroelectric dipoles of the ferroelectric material. In some examples, such an implementation may support relatively faster programming (e.g., in accordance with a polarization change of the ferroelectric material) or relatively lower power consumption than a memory device with other implementations of charge-trapping materials or NAND architectures (e.g., associated with a reduction of electron transfer to write or erase a given logic state, associated with relatively lower voltages to induce a dipole polarization than perform charge transfer). However, some such implementations of ferroelectric material may have other performance tradeoffs. For example, some implementations of a ferroelectric material in such architectures may be associated with relatively high read latency, a relatively high erase latency, or both (e.g., due to relatively low current in vertical channels of a 3D NAND array, due to a relatively high capacitance of planar word lines implemented in a 3D NAND array, or both), or may prevent byte alterability (e.g., due to an erase granularity being different than a write granularity), among other drawbacks.

In accordance with the techniques described herein, to improve performance of memory cells 105 within a dense array, the memory device 100 may implement a NOR structure, where each memory cell 105 along a column of the array may be connected to vertical source lines and bit lines (e.g., otherwise referred to as drain lines, along the z-direction). For example, the memory device 100 may implement an architecture that integrates a relatively high-density array of Fe-FETs in a NOR configuration, thereby enabling the memory device 100 to realize improved read and program performance, relatively quicker random-access procedures, relatively improved byte alterability, and experience reduced power consumption (e.g., lower energy) for a variety of applications.

For example, the memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array (e.g., a memory array) of the memory device 100, where, in some examples, an array may refer to a contiguous set of memory cells 105 (e.g., a contiguous set of elements of a semiconductor chip).

Each memory cell 105 may be implemented as a transistor (e.g., an Fe-FET) that is configured for storing an electric field representative of a logic state. For example, the blow-up of FIG. 1 illustrates a memory cell 105 (e.g., an FeNOR memory cell, an FeFET memory cell, a ferroelectric memory cell) that includes a transistor 110 that may be used to store a logic value. The transistor 110 may include a gate 115 (e.g., a gate portion, a control gate), a dielectric portion 120 (e.g., a gate dielectric), a ferroelectric portion 125 (e.g., a polarization portion, a portion including ferroelectric dipoles 126, a portion for storing an electric field corresponding to a logic state), a channel interlayer portion (not shown), and a channel portion 130 (e.g., including one or more semiconductor material portions, a doped semiconductor channel). The transistor 110 also may include a first node 135-a (e.g., a source or drain associated with the channel portion 130) and a second node 135-b (e.g., a drain or source associated with the channel portion 130). An electric field stored at a memory cell 105 (e.g., stored at least in part by a polarization of a ferroelectric portion 125) may affect the threshold voltage of the transistor 110 (e.g., a voltage at a gate 115 to activate the channel portion 130, an activation voltage), thereby affecting an amount of current that may through the transistor 110 when the gate 115 is biased (e.g., when a voltage is applied to the gate 115, when a voltage is applied to a word line 150, when the memory cell 105 is read).

A logic value may be stored in a memory cell 105 (e.g., in a transistor 110) by inducing (e.g., writing, storing) an electric field in the memory cell 105. For example, an electric field corresponding to a logic state may be stored based at least in part on storing a polarization (e.g., a dipole polarization, a polarization orientation, a dipole orientation, a local electric field orientation) in a ferroelectric portion 125, where different polarizations may correspond to different logic states. For example, a memory cell 105 may be written with a cell state 190 (e.g., an electric field state, a polarization state, a written state, corresponding to a logic state), such as either a cell state 190-a (e.g., a “PROGRAM” state) or a cell state 190-b (e.g., an “ERASE” state). In the illustrated examples, a cell state 190-a may correspond to a first polarization of a ferroelectric portion 125 (e.g., a first orientation of dipoles 126, corresponding to a positive local electric field from a gate 115 to a channel portion 130), and a cell state 190-b may correspond to a second polarization of a ferroelectric portion 125 (e.g., a second orientation of dipoles 126, corresponding to a negative local electric field from a gate 115 to a channel portion 130). In some examples, the cell state 190-a may be associated with supporting a relatively lower voltage at a gate 115 to activate a channel portion 130 (e.g., a relatively higher activation voltage, a relatively lower conductivity through the channel portion 130 for a given voltage at the gate 115), whereas the cell state 190-b may be associated with supporting a relatively higher voltage at a gate 115 to activate a channel portion 130 (e.g., a relatively lower activation voltage, a relatively higher conductivity through the channel portion 130 for the given voltage at the gate 115).

In some examples, an electric field corresponding to a logic state may also be associated with storing an electric charge, such as by way of electron transfer into or out of a portion of the memory cell 105 (e.g., a dielectric portion 120, a channel interlayer portion, a charge trapping material included in combination with a ferroelectric portion 125, the ferroelectric portion 125 itself, or a combination thereof). For example, an electric field associated with the cell state 190-a may also include a net positive charge (e.g., in addition to a polarization of a ferroelectric portion 125, as stored in a dielectric portion 120, as a result of transferring electrons from the memory cell 105, as a result of hole injection), and an electric field associated with the cell state 190-b may also include a net negative charge (e.g., in addition to a polarization of a ferroelectric portion 125, as stored in a dielectric portion 120, as a result of transferring electrons into the memory cell 105, as a result of electron injection).

In the example of memory device 100, the memory cells 105 may be configured in planes 145 (e.g., in an xy-plane, memory cells 105 arranged along the x-direction and the y-direction) and along pillars 140 (e.g., third pillars including memory cells 105 arranged along the z-direction). For example, a plane 145 of memory cells 105, or subset thereof, may be coupled with a respective word line 150 (e.g., WL₁ through WL_{M}, a planer word line, a word line comb), and each pillar 140 of memory cells 105 may be coupled with a respective bit line 160-a (e.g., BL₁ through BL_{N}) and a respective source line 160-b (e.g., SL₁ through SL_{N}). Each of the word lines 150, bit lines 160-a, and source lines 160-b may be an example of an access line of the memory device 100. In the example of memory device 100, one memory cell 105 may be located at the intersection of (e.g., coupled with, coupled between) a word line 150 and a paired bit line 160-a and source line 160-b. This intersection may be referred to as an address of a memory cell 105. A target (e.g., selected) memory cell 105 may be a memory cell 105 located at the intersection of an activated or otherwise selected word line 150 and an activated or otherwise selected bit line 160-a and source line 160-b.

The memory device 100 may include a 3D memory array, where multiple two-dimensional (2D) memory arrays (e.g., planes 145, in xy-planes) may be formed on top of one another (e.g., along the z-direction). In some examples, such an arrangement may increase the quantity of memory cells 105 that may be fabricated on a single die or substrate as compared with 2D arrays, which, in turn, may reduce production costs, or increase the performance of the memory array, or both. In the example of FIG. 1, memory device 100 includes multiple planes 145 (e.g., decks, layers, levels, tiers) of memory cells 105. The planes 145 (e.g., word lines 150) may, in some examples, be separated by an electrically insulating material. Each plane 145 may be aligned or positioned so that memory cells 105 may be aligned (e.g., exactly aligned, overlapping, or approximately aligned) with one another across each plane 145, forming a memory cell 105 stack along the z-direction (e.g., along a pillar).

Access operations such as reading, writing, rewriting, and refreshing may be performed on a memory cell 105 by activating (e.g., selecting) a word line 150, a bit line 160-a, and a source line 160-b coupled with the memory cell 105, which may include applying a voltage, a charge, or a current to the respective access line. After selecting a memory cell 105 (e.g., in a read operation), a resulting signal may be used to determine the logic state stored by the memory cell 105.

Accessing memory cells 105 may be controlled using a word line component 155 (e.g., a row decoder, a word line decoder), a pillar component 165 (e.g., a pillar decoder, a column decoder), or both, among other component architectures. For example, the word line component 155 may receive a row address from the memory controller 180 and activate a corresponding word line 150 based on the received row address. Similarly, the pillar component 165 may receive a column address from the memory controller 180 and activate a corresponding bit line 160-a and a corresponding source line 160-b.

In some examples, the memory controller 180 may control operations (e.g., read operations, write operations, rewrite operations, refresh operations) of memory cells 105 using one or more components (e.g., word line components 155, pillar components 165, sense components 170, input/output components 175). In some cases, one or more of the word line component 155, the pillar component 165, and the sense component 170 may be co-located with or otherwise included as part of the memory controller 180. The memory controller 180 may generate row and column address signals to activate a desired word line 150, bit line 160-a, and source line 160-b. The memory controller 180 may also generate or control various voltages or currents used during the operation of memory device 100.

A memory cell 105 may be written (e.g., programmed, set) by activating the relevant word line 150, bit line 160-a, and source line 160-b (e.g., via a memory controller 180). In other words, a logic state may be stored in a memory cell 105. A word line component 155, pillar component 165, or both may accept data, for example, via input/output component 175, to be written to the memory cells 105. In some examples, a write operation may be performed at least in part by a sense component 170, or a write operation may be configured to bypass a sense component 170.

A memory cell 105 may be read (e.g., sensed) by a sense component 170 when the memory cell 105 is accessed (e.g., in cooperation with the memory controller 180) to determine a logic state written to or stored by the memory cell 105. For example, the sense component 170 may be configured to evaluate a current or charge transfer through or from the memory cell 105, or a voltage resulting from coupling the memory cell 105 with the sense component 170, responsive to a read operation. The sense component 170 may provide an output signal indicative of the logic state read from the memory cell 105 to one or more components (e.g., to the pillar component 165, the input/output component 175, to the memory controller 180).

A sense component 170 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 170 may include a collection of circuit elements that are repeated for each of a set or subset of bit lines 160-a, source lines 160-b, or both that are coupled with the sense component 170. For example, a sense component 170 may include a separate sensing circuit (e.g., a separate or duplicated sense amplifier, a separate or duplicated signal development component) for each of a set of bit lines 160-a, each of a set of source lines 160-b, or both that are coupled with the sense component 170, such that a logic state may be separately detected for respective memory cells 105.

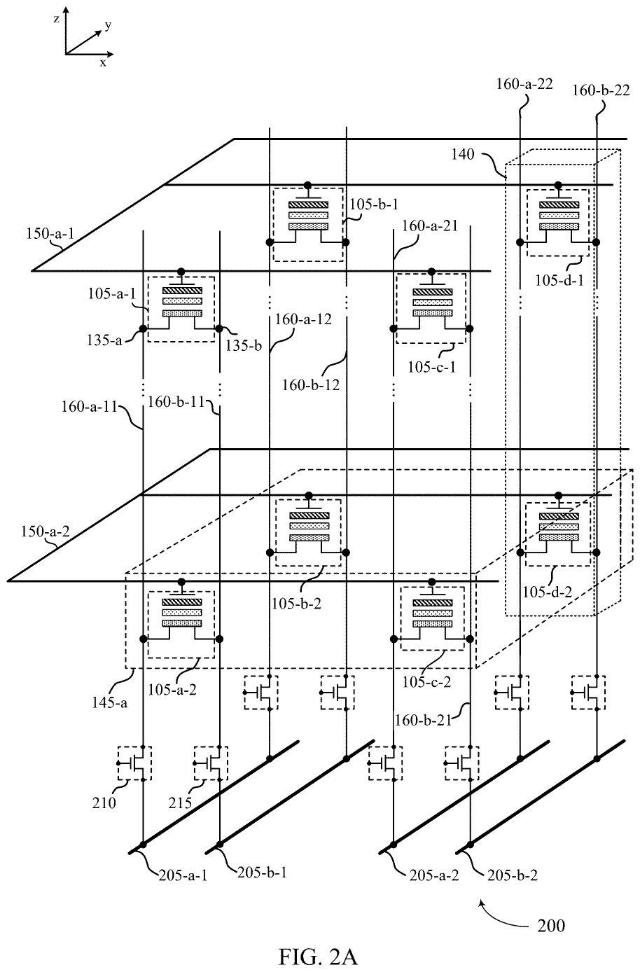

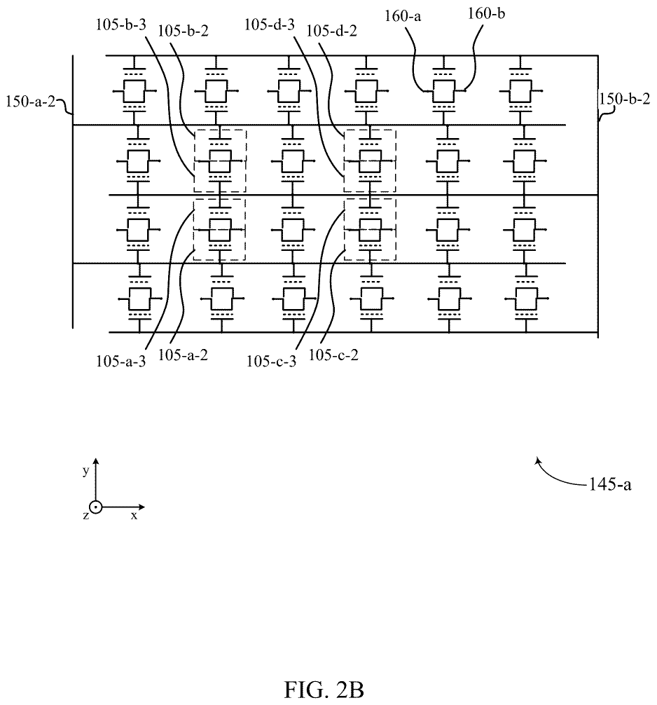

FIGS. 2A and 2B show examples of an architecture 200 (e.g., an array architecture, a memory array) that supports FeNOR memory architectures in accordance with examples as disclosed herein. The architecture 200 may be an example of portions of a memory device, such as a memory device 100. Although some elements of a set of elements (e.g., an array of elements) are included in FIGS. 2A and 2B, some elements may be omitted for the sake of visibility and clarity of the depicted elements. Moreover, although some elements included in FIGS. 2A and 2B are labeled with reference numbers, some other corresponding elements are not labeled, though they would be understood by a person having ordinary skill in the art to be the same as or similar to the labeled elements. Aspects of an architecture 200 may be described with reference to an x-direction, a y-direction, and a z-direction of the illustrated coordinate system.

The architecture 200 illustrates a 3D array of memory cells 105 (e.g., transistors 110), which may be connected in a 3D NOR configuration. For example, memory cells 105 may be arranged according to pillars 140 (e.g., columns, of memory cells 105) along the z-direction, each of which may include one or more (e.g., two) stacks of memory cells 105 along the z-direction. In some examples, each pillar 140 may be associated with a channel (e.g., a semiconductor channel, a semiconductor pillar) along the z-direction. A memory device 100 may include any quantity of one or more pillars 140 in accordance with examples as disclosed herein. In some implementations, each pillar 140 may include a first set of memory cells 105 at a first side of the pillar 140 (e.g., along the y-direction) and include a second set of memory cells 105 at a second side of the pillar 140 opposite the first side (e.g., along the y-direction). As illustrated, a first pillar 140 may include the memory cells 105-d-1 through 105-d-2 (e.g., positioned at a first side of the first pillar 140 along the y-direction) and, in some examples (not shown), may include a second set of memory cells 105 (e.g., positioned at a second side of the first pillar 140). Similarly, another pillar 140 may include the memory cells 105-a-1 through 105-a-2 (e.g., at a first side of the other pillar 140) and, in some examples (not shown), may include a second set of memory cells 105 (e.g., positioned at the second side of the other pillar 140), and so on.

Each pillar 140 may be associated with and positioned between a respective bit line 160-a (e.g., a conductive pillar) and a respective source line 160-b (e.g., a conductive pillar), and each memory cell 105 along a pillar 140 may be coupled with the same bit line 160-a and the same source line 160-b. For example, a same bit line 160-a may be coupled with the first node 135-a (e.g., a drain node) of each memory cell 105 (e.g., transistor 110) of a pillar 140, while a same source line 160-b may be coupled with the second node 135-b (e.g., a source node) of each memory cell 105 (e.g., transistor 110) of the pillar 140. As illustrated, the first nodes 135-a of the memory cells 105-a-1 through 105-a-2 may be coupled with the bit line 160-a-11, while the second nodes 135-b of the memory cells 105-a-1 through 105-a-2 may be coupled with the source line 160-b-11.

In some examples, the bit lines 160-a of one or more pillars 140 (e.g., in a group along the y-direction) may be coupled (e.g., selectively, via a transistor 210, via a pillar component 165) with a same bit line selector 205-a (e.g., an access line, a multiplexing line). For example, the bit line 160-a-11 coupled with memory cells 105-a of one pillar 140 and the bit line 160-a-12 coupled with memory cells 105-b of another pillar 140 may both be coupled (e.g., via a respective transistor 210) with the bit line selector 205-a-1. Likewise, the bit line 160-a-21 coupled with memory cells 105-c of one pillar 140 and the bit line 160-a-22 coupled with memory cells 105-d of another pillar 140 may both be coupled with the bit line selector 205-a-2. Although illustrated as being at a first end (e.g., bottom) of the architecture 200 (e.g., along the z-direction), it should be understood that such bit line selectors 205-a may be positioned at a second end (e.g., top) of the architecture 200 (e.g., along the z-direction). Transistors 210 may be coupled with activation lines (e.g., extending along the x-direction, coupled with gates of the transistors 210) and operated in accordance with various multiplexing and addressing techniques.

In some examples, the source lines 160-b of one or more pillars 140 (e.g., in a group along the y-direction) may be coupled (e.g., selectively, via a transistor 215, via a pillar component 165) with a same source line selector 205-b (e.g., an access line, a multiplexing line, a common source). For example, the source line 160-b-11 coupled with memory cells 105-a of one pillar 140 and the source line 160-b-12 coupled with memory cells 105-b of another pillar 140 may both be coupled (e.g., via a respective transistor 215) with the source line selector 205-a-1. Likewise, the source line 160-b-21 coupled with memory cells 105-c of one pillar 140 and the source line 160-b-22 coupled with memory cells 105-d of another pillar 140 may both be coupled with the source line selector 205-b-2. Although illustrated as being at a first end (e.g., bottom) of the architecture 200 along the z-direction, it should be understood that such source line selectors 205-b may be positioned at a second end (e.g., top) of the architecture 200 along the z-direction. Transistors 215 may be coupled with activation lines (e.g., extending along the x-direction, coupled with gates of the transistors 215) and operated in accordance with various multiplexing and addressing techniques.

In the example of architecture 200, the array of memory cells 105 may also be divided into a set of planes 145 arranged along the z-direction, including the plane 145-a associated with memory cells 105-a-2 through 105-d-2, and so on. In some examples, all memory cells 205 of a plane 145 may be activated by a same word line 150. In some other examples, subsets of memory cells 205 of a given plane 145 may be activated by a respective one of multiple word lines 150 associated with the given plane 145. For example, a plane 145 may be associated with word lines 150 configured in accordance with a comb structure (e.g., even and odd word lines 150). Such combed word lines 150 may be formed such that portions of the word line 150 (e.g., conductor portions, projections, tines) extend along the x-direction through gaps (e.g., alternating gaps) between pillars 140. For example, the architecture 200 may include two word lines 150 per plane 145 (e.g., according to odd word lines 150-a-1 and 150-a-2, with projections along the positive x-direction, and even word lines 150-b-1 (not shown) and 150-b-2 (e.g., as illustrated by the plane 145-a of FIG. 2B), with projections along the negative x-direction, where such word lines 150 of the same plane 145 may be described as being interleaved (e.g., with portions of an odd word line 150-a-2 projecting along the x-direction between portions of an even word line 150-b-2, and vice versa). In some examples, an even word line 150-b (e.g., of a plane 145) may be associated with a first memory cell 105 on a first side (e.g., along the y-direction) of a given pillar 140 and an odd word line 150-a (e.g., of the same plane 145) may be associated with a second memory cell 105 on a second side (e.g., along the y-direction, opposite the first memory cell 105) of the given pillar 140. Thus, in some examples, memory cells 105 of a given plane 145 may be addressed (e.g., selected, activated, multiplexed) in accordance with an even word line 150 or an odd word line 150.

FIG. 2B shows a top-down view of a plane 145-a that may be implemented in the architecture 200, illustrating a combed word line structure. As illustrated, the word line 150-a-2 may have portions that extend (e.g., into the array of memory cells 105) along the positive x-direction, and the word line 150-b-2 may have portions that extend along the negative x-direction. Accordingly, the memory cells 105-a-2, 105-b-2, 105-c-2, and 105-d-2 may be coupled with (e.g., activated by) the word line 150-a-2 (e.g., an odd word line), and the memory cells 105-a-3, 105-b-3, 105-c-3, and 105-d-3 (e.g., opposite the memory cells 105-a-2, 105-b-2, 105-c-2, and 105-d-2 along the y-direction) may be coupled with the word line 150-b-2 (e.g., an even word line).

To operate the architecture 200 (e.g., to perform a program operation, a read operation, or an erase operation on one or more memory cells 105 of a pillar 140), various voltages may be applied to one or more word lines 150 (e.g., to one or more gates of the transistors 110), to one or more bit lines 160-a (e.g., to first node 135-a or drain of one or more transistors 110), to one or more source lines 160-b (e.g., to the second node 135-b or source of the transistors 110), or any combination thereof.

In some cases, as part of a program operation for a target memory cell 105, a polarization (e.g., a dipole polarization, a stored electric field) may be induced by applying an electric field (e.g., a coercive field, a saturation field, a polarizing field) across a ferroelectric portion 125 of the target memory cell 105. Additionally, in some examples, an electric charge may be induced (e.g., injected, by way of charge transfer, by way of electron transfer) based on applying the electric field (e.g., across the memory cell), in which case a charge stored in a charge-trapping material may accompany a polarization to store a logic state at the memory cell 105. In some cases, respective voltages may be applied to word line(s) 150, bit line(s) 160-a, and source line(s) 160-b, such that a gate 115 of the target memory cell 105 is at a higher voltage than the first node 135-a and the second node 135-b of the target memory cell 105 (e.g., a relatively positive voltage may be applied to the word line, to store a “PROGRAM” state, to store a cell state 190-a). This may cause the electric field across features of the memory cell 105 (e.g., between the gate 115 and channel portion 130) such that a first polarization is induced into the ferroelectric portion 125 of the target memory cell 105, a positive charge is injected into a portion of the target memory cell 105, or both.

In such examples (e.g., program operation), the first polarization in the ferroelectric portion 125 may create a first dipole, where a concentration (e.g., a localization) of positive charges may be stored at a first side of the ferroelectric portion 125 and a concentration (e.g., a localization) of negative charges may be stored at a second side of the ferroelectric portion 125 opposite the first side. In such examples, the first side of the ferroelectric portion 125 may be in contact with or otherwise toward the channel portion 130 of the target memory cell 105, while the second side of the ferroelectric portion 125 may be in contact with the channel interlayer portion of the target memory cell 105 or otherwise toward a gate 115.

In some cases, as part of an erase operation for a memory cell 105 (e.g., to store an “ERASE” state, to store a cell state 190-b), the polarization of charge in the ferroelectric portion 125 of a memory cell may be changed (e.g., reversed). Additionally, in some examples, a charge stored in a portion of the memory cell 105 may be reversed as part of the erase operation. In some cases, respective voltages may be applied to word line(s) 150, bit line(s) 160-a, and source line(s) 160-b, such that a gate 115 of the target memory cell 105 is at a lower voltage than the first node 135-a and the second node 135-b of the target memory cell 105 (e.g., a relatively negative voltage may be applied to the word line). This may cause an electric field across the features of the memory cell 105 (e.g., between the gate 115 and the channel portion 130), such that a second polarization is induced into the ferroelectric portion 125 of the target memory cell 105, a negative charge is injected into a portion of the target memory cell 105, or both.

In such examples (e.g., erase operation), the second polarization of charge in the ferroelectric portion 125 may create a second dipole, where a concentration of negative charges may be stored at the first side of the ferroelectric portion 125 and a concentration of positive charges may be stored at the second side of the ferroelectric portion 125 opposite the first side. In such examples, the first side of the ferroelectric portion 125 may be in contact with or otherwise toward the channel portion 130 of the target memory cell 105, while the second side of the ferroelectric portion 125 may be in contact with the channel interlayer portion of the target memory cell 105 or otherwise toward a gate 115.

In some cases, as part of a read operation for a target memory cell 105, a positive voltage may be applied to the corresponding bit line 160-a, while the corresponding source line 160-b may be grounded or otherwise biased with a voltage lower than the voltage applied to the bit line 160-a. Additionally, the corresponding word line 150 may be biased with a positive voltage (e.g., to potentially activate the memory cell 105, based on a level of charge stored in the ferroelectric portion 125), which may be greater than the positive voltage applied to the corresponding bit line 160-a but may be less than a voltage applied during programming of the target memory cell 105. In this way, by biasing the corresponding bit line 160-a, the source line 160-b, and the word line 150, the logic value of the target memory cell 105 may be read (e.g., evaluating whether the target memory cell 105 stores a cell state 190-a or a cell state 190-b).

A signal on the bit line 160-a-11 corresponding to the memory cell 105-a-1 (e.g., an amount of current, such as a current below or above a threshold) may be sensed (e.g., by a sense component 170) and may indicate whether the memory cell 105-a-1 became conductive (e.g., if written to a cell state 190-a) or remained non-conductive (e.g., if written with a cell state 190-b) in response to the application of the various voltages. The sensed signal thus may be indicative of whether the memory cell 105 was in an erased state (e.g., an “ERASE” state, storing a logic 1) or a programmed state (e.g., a “PROGRAM” state, storing a logic 0), or some other state (e.g., of a multiple-level configuration of the memory cell 105-a-1). That is, the sense component 170 may determine a logic state of the memory cell 105-a-1 based on the signal generated on the bit line 160-a-11 according to biasing the word line 150-a-1 with the second voltage, biasing the source line 160-b-11 with the ground voltage, and on biasing the bit line 160-a-11 with the third voltage.

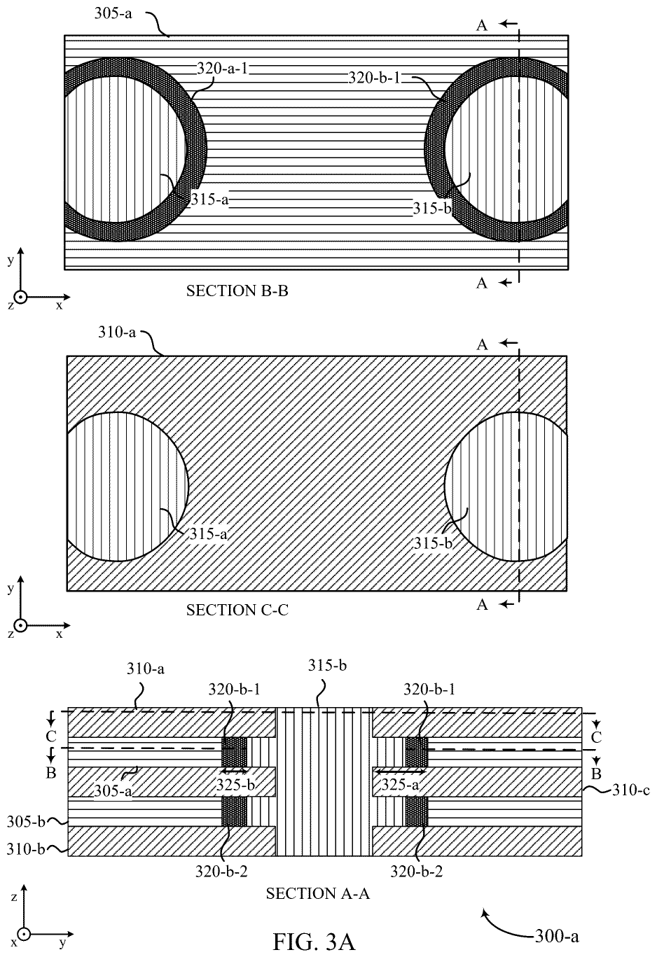

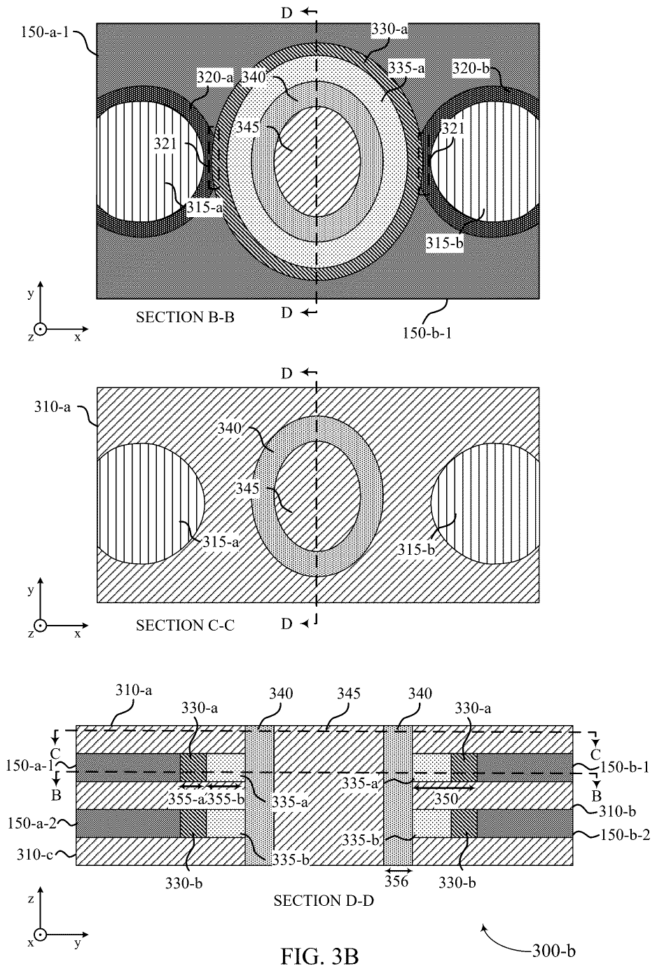

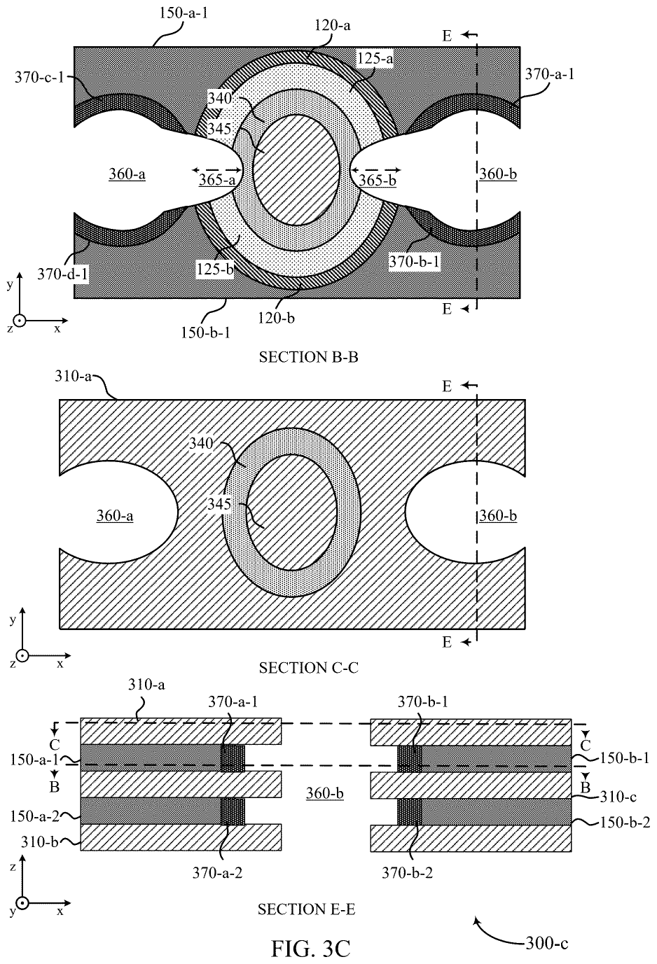

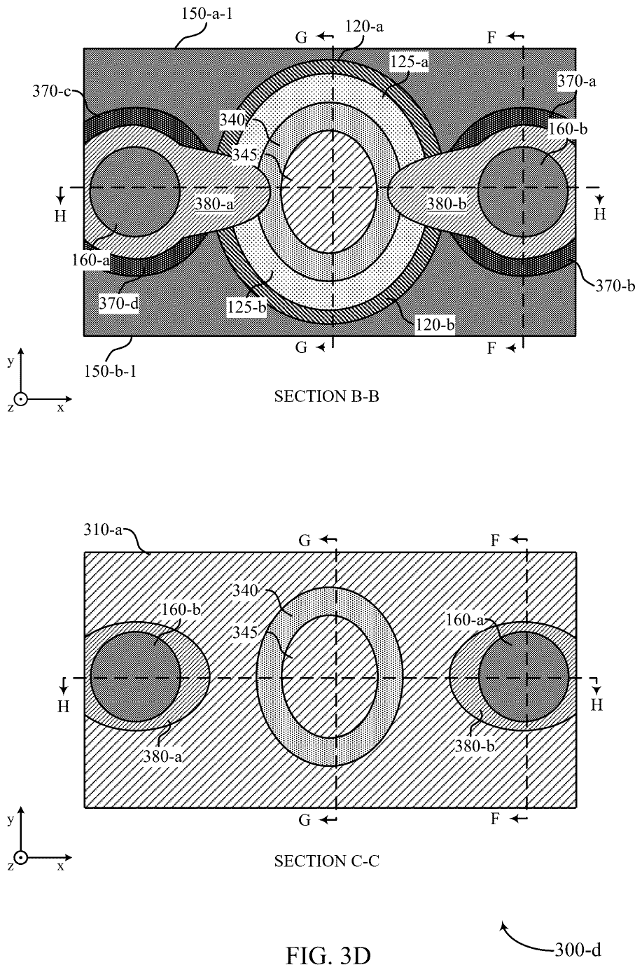

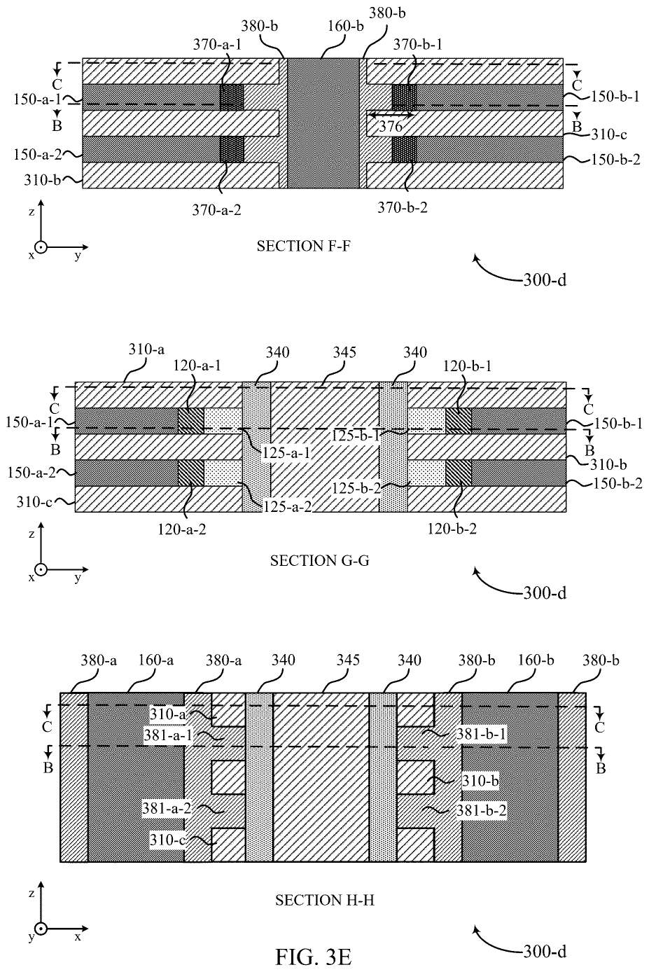

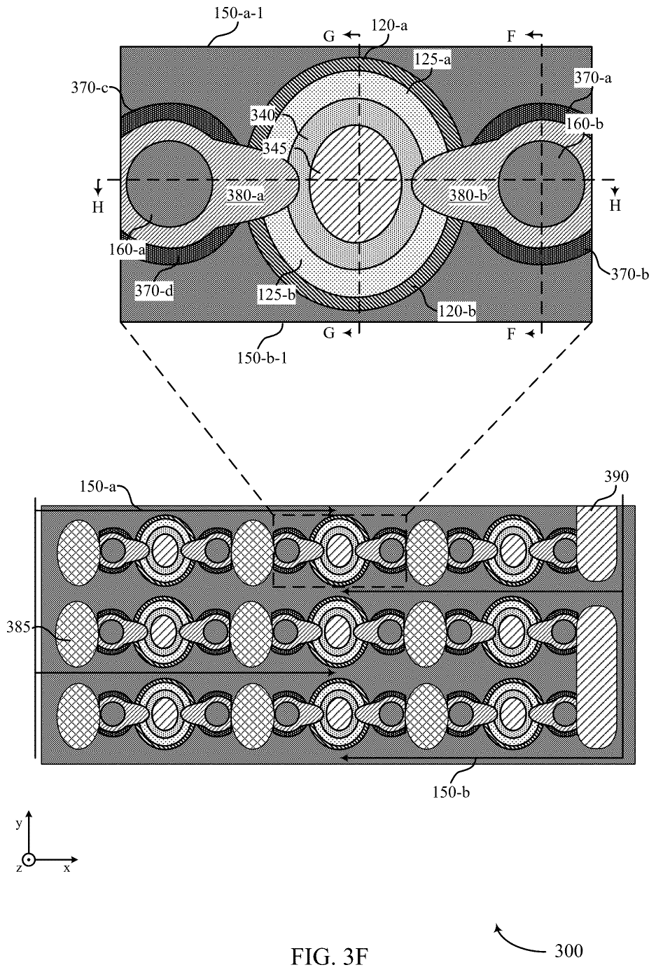

FIGS. 3A, 3B, 3C, 3D, 3E, and 3F show examples of fabrication operations that support FeNOR architectures in accordance with examples as disclosed herein. For example, FIGS. 3A through 3F may illustrate a sequence of operations for fabricating aspects of an architecture 300 (e.g., as a portion of a semiconductor wafer), which may implement aspects of a memory device 100, or an architecture 200, or another implementation of a semiconductor component (e.g., a memory component). In some examples, the architecture 300 may be a portion of memory die, or a wafer that includes multiple memory dies, such as NOR die (e.g., a 3D-NOR die, a die having an arrangement of NOR memory cells in a three-dimensional array). Although some elements included in FIGS. 3A through 3F are labeled with reference numbers, some other corresponding elements are not labeled, though they would be understood by a person having ordinary skill in the art to be the same as or similar to the labeled elements.

Each of FIGS. 3A through 3F may illustrate aspects of the architecture 300 after different subsets of the fabrication operations for forming the architecture 300 (e.g., illustrated as an architecture 300-a after a first set of one or more fabrication operations, as an architecture 300-b after a second set of one or more fabrication operations, and so on). Each view of FIGS. 3A through 3F may be described with reference to an x-direction (e.g., a first direction over a substrate, not shown), a y-direction (e.g., a second direction over the substrate), and a z-direction (e.g., a direction from the substrate) of the illustrated coordinate system, which may correspond to the respective directions described with reference to the architecture 200. Aspects of the architecture 300 may be illustrated in accordance with cross-sectional section views A-A (e.g., in a yz-plane), B-B (e.g., in an xy-plane), C-C (e.g., in an xy plane), D-D (e.g., in a yz-plane), E-E (e.g., in an xz-plane), F-F (e.g., in a yz-plane), G-G (e.g., in yz-plane), and H-H (e.g., in a xz-plane) to show embedded features of the architecture 300.

FIG. 3A shows the architecture 300 (e.g., as an architecture 300-a) after a first set of one or more fabrication operations.

For example, a stack of layers (e.g., layers in a respective xy-plane) may be formed over a substrate, and the stack of layers may include nitride layers 305 and oxide layers 310 that are alternating along the z-direction. As illustrated in the cross-sectional view A-A, the stack of layers may be formed to include oxide layers 310-a, 310-b, and 310-c, with a nitride layer 305-a between the oxide layers 310-a and 310-b and a nitride layer 305-b between the oxide layers 310-b and 310-c. An architecture 300 may include any quantity of nitride layers 305 and oxide layers 310, and a quantity of nitride layers 305 may, in some examples, correspond to a quantity of memory cells 105 in pillars 140 of a memory device 100. After forming the stack of layers, multiple cavities may be formed through the stack of layers along the z-direction (e.g., terminating at or above the substrate), which may be formed using an etching procedure (e.g., a dry etch, a directional etch, a laser material removal operation, among other examples). For example, a first cavity may be formed, corresponding to the pillar 315-a, and a second cavity may be formed, corresponding to the pillar 315-b. In such examples, the cavities may be formed in a circular shape (e.g., as a cross-section in an xy-plane), as illustrated in FIG. 3A. In some other examples, the cavities may be formed in an elliptical shape, a square shape, a rectangular shape, a rounded rectangular shape, or any combination thereof.

In some examples, one or more voids (e.g., third voids and fourth voids) may be formed in each nitride layer 305 of the stack of layers. For example, a procedure (e.g., nitride recess procedure, a wet etch operation) may be performed through each of the cavities (e.g., cavities associated with the pillars 315) to recess (e.g., remove, along one or more directions in respective xy-planes) a respective portion 325-a of nitride from each nitride layer (e.g., in directions of an xy-plane from a sidewall of the cavities), thereby forming the one or more voids into each nitride layer 305 (e.g., between oxide layers 310). As shown in the cross-sectional view A-A, respective portions 325-a of the nitride layers 305-a and 305-b may be recessed, thereby forming a respective void (e.g., a fourth void).

After forming the one or more voids, a first dielectric material (e.g., silicon oxide (SiOx)) may be deposited into the cavities and into the voids. Based on depositing the first dielectric material into the cavities and the one or more voids, a portion of the first dielectric material may be removed (e.g., selectively etched, recessed at a nitride layer) to reform the cavities (e.g., corresponding to the pillars 315), thereby forming the portions 320 into each void of the nitride layers 305. For example, a respective portion 320-a of the first dielectric material may be formed into each void through a first cavity, and a respective portion 320-b may be formed into each void through a second cavity. As illustrated in the cross-sectional view A-A, a portion 320-b-1 may be formed into the void of the nitride layer 305-a, and a portion 320-b-2 may be formed into the void of the nitride layer 305-b (e.g., with a recession into the voids). In some examples, as illustrated, the portions 320 of the first dielectric material may be formed in a portion 325-b of the voids at each nitride layer 305. In some other examples, the portions 320 of the first dielectric material may be formed to fill the portion 325 removed from each nitride layer 305. That is, the portions 320 of the first dielectric material may be formed to fill each void in the word line deck (e.g., without recession).

After forming the portions 320 of the first dielectric material, the pillars 315 may be formed. For example, a sacrificial material (e.g., silicon carbonitride (SiCN), spin-on dielectric (SOD)) may be formed into each cavity, thereby forming the pillars 315-a (e.g., a first pillar) and 315-b (e.g., a second pillar). As such, each respective portion 320 may be continuous around a respective pillar 315.

FIG. 3B shows the architecture 300 (e.g., as an architecture 300-b) after a second set of one or more fabrication operations.

For example, multiple third cavities (e.g., third cavities corresponding to the pillar 345 and the first semiconductor material 340) may be formed through the stack of layers along the z-direction (e.g., terminating at or above the substrate). In such examples, each third cavity may be formed between a respective pillar 315-a and a respective pillar 315-b. As illustrated, the third cavities may be formed in an elliptical shape (e.g., in the xy-plane), however, the cavities may be formed in a circular shape, a square shape, a rectangular shape, a rounded rectangular shape, or any combination thereof.

As a result of forming the third cavities, the nitride layers 305 may be divided into a comb structure, with multiple first nitride layers 305 at a first side of the third cavities along the y-direction and multiple second nitride layers 305 at a second side of the third cavities opposite the first side along the y-direction. That is, by forming the third cavities, each nitride layer 305 may divided into a first nitride layer 305 and a second nitride layer 305.

After forming the third cavities (e.g., corresponding to the pillar 345 and the first semiconductor material 340), a second dielectric material (e.g., aluminum oxide (AlOx), hafnium oxide (HfOx), silicon oxycarbide (SIOC), SiCN, silicon dioxide, or a combination thereof) may be formed into each third cavity. Accordingly, a subset of the third cavities (e.g., cavities associated with the active pillars, pillars between a bit line 160-a and a source line 160-b) chosen to include memory cells 105 may undergo a dielectric exhume and cell integration process, and a remaining subset of third cavities may remain protected by a mask and not open for the exhume operation. That is, after forming the third cavities, the second dielectric material may be formed into each third cavity, thereby forming dielectric pillars (not shown). The dielectric material deposited into the third cavities associated with an active pillar may be exhumed (e.g., removed), thereby re-exposing the corresponding third cavity. In some examples, after exhuming the second dielectric material to reform the third cavities, a portion 321 of each portion 320-a of the first dielectric material may be removed (e.g., pillar oxide partial etch back).

In some examples, after exhuming the second dielectric material, multiple word lines 150-a (e.g., odd word lines, conductors, formed using tungsten, molybdenum, or ruthenium) may be formed in place of the multiple first nitride layers 305 and multiple word lines 150-b (e.g., even word lines, conductors, formed using tungsten, molybdenum, or ruthenium) may be formed in place of the multiple second nitride layers 305. For example, after exhuming the second dielectric material to reform the third cavities, multiple first voids may be formed, for example, by exhuming, through the reformed third cavities, the nitride material from each of the multiple first nitride layers 305. Multiple second voids may be formed by exhuming, through the reformed third cavities, the nitride material from each of the multiple second nitride layers 305. A respective word line 150-a of the multiple word lines 150-a may be formed into a respective first void of the multiple first voids, and a respective word line 150-b of the multiple word lines 150-b may be formed into a respective second void of the multiple second voids. As shown in the cross-sectional view D-D, the nitride layer 305-a may be replaced by the word line 150-a-1 and the word line 150-b-1, and the nitride layer 305-b may be replaced by the word line 150-a-2 and the word line 150-b-2.

After forming the word lines 150, a procedure (e.g., metal recession procedure) may be performed to recess (e.g., remove) a respective portion 350 of metal from each word line 150, thereby forming multiple voids into each word line 150. For example, a respective first void may be formed into each word line 150-a through a first side of a respective third cavity, and a respective second void may be formed into each word line 150-b through a second side of a respective third cavity opposite the first side along the y-direction. As illustrated in the cross-sectional view D-D, a portion 350 of the word lines 150-a-1, 150-a-2, 150-b-1, and 150-b-2 may be recessed.

Subsequently, multiple portions 330 of a third dielectric material (e.g., interlayer portions, a same dielectric material as the first or second dielectric material, a different dielectric material from the first or second dielectric material) may be formed into portions 355-a of the multiple voids in the word lines 150 and into portions 321 removed from the portions 320. For example, the third dielectric material (e.g., interlayer) may be formed into each exposed third cavity and into the respective voids of the word lines 150. Accordingly, a portion of the third dielectric material may be exhumed to reform each third cavity and form a portion 355-b of each void of the word lines 150. By doing so, a respective portion 330 may be formed into a respective void of word lines 150 and be positioned (e.g., recessed or confined) between each oxide layer 310 and be in contact with a respective word line deck. In some other examples, the third dielectric material may be selectively deposited into the portion 355-a (e.g., into nitride layers 305, between oxide layers 310), thereby forming the portions 330 of the third dielectric material. As illustrated in the cross-sectional view D-D, a portion 330-a of the third dielectric material may be formed into the word lines 150-a-1 and 150-b-1, and a portion 330-b of the third dielectric material may be formed into the word lines 150-a-2 and 150-b-2 (e.g., each forming a ring of the third dielectric material).

After forming the portions 330, multiple portions 335 of a storage material (e.g., one or more materials, a ferroelectric material, a combination of a ferroelectric material and a charge-trapping material) may be formed into the portions 355-b of the multiple voids in the word lines 150. For example, a ferroelectric material may be formed into each exposed third cavity and into the portions 355-b of each void between oxide layers 310. Subsequently, a portion of the ferroelectric material may be exhumed to reform each third cavity. By doing so, a respective portion 335 may be formed in a respective void of the word lines 150 and be positioned (e.g., recessed into, or confined) between each oxide layer 310 and be in contact with a respective portion 330 of the third dielectric material. Alternatively, after forming the portions 320, the ferroelectric material may be selectively deposited into the portion 355-b, thereby forming the portions 335 of the storage material. For example, as shown in the cross-sectional view D-D, a portion 335-a of the storage material may be formed into the word lines 150-a-1 and 150-b-1, and a portion 335-b of the storage material may be formed into the word lines 150-a-2 and 150-b-2 (e.g., each forming a ring of the storage material within a ring of the third dielectric material).

After forming the portions 335, the first semiconductor material 340 (e.g., p-type doped polysilicon) may be formed (e.g., deposited) along a sidewall of each third cavity according to a selected thickness 356, and the first semiconductor material 340 may be in contact with each portion 335 of the storage material. Due to forming the first semiconductor material 340 along the sidewall of each cavity, a respective fourth cavity may be formed. In some examples, an etching procedure may be performed to adjust (e.g., decrease) the thickness 356 of the first semiconductor material 340. After forming the first semiconductor material 340, a respective pillar 345 may be formed into each fourth cavity. For example, an oxide material (e.g., core dielectric material, which may be a same oxide as the oxide layers 310 or a different oxide than the oxide layers 310) may be formed into the fourth cavities to form the pillars 345. As shown in the cross-sectional view D-D, the first semiconductor material 340 may extend along a length of the pillar 345 along the z-direction and be between the pillar 345 and the portions 335 of the storage material.

FIG. 3C shows the architecture 300 (e.g., as an architecture 300-c) after a third set of one or more fabrication operations.

For example, one or more cavities 360 may be formed by exhuming (e.g., removing) the sacrificial material from each pillar 315. For example, a cavity 360-a may be formed by exhuming the sacrificial material of the pillar 315-a, and the cavity 360-b may be formed by exhuming the sacrificial material of the pillar 315-b. After or as part of forming the cavities 360, a respective void 365-a (e.g., a first void) may be formed (e.g., via a wet etch, a directional etch, or a dry etch procedure) through each portion 320-a, each portion 330, and each portion 335 to expose the first semiconductor material 340 along a first side of the pillar 345 along the x-direction. Further, a respective void 365-b (e.g., a second void) may be formed (e.g., via a wet etch, a directional etch, or a dry etch procedure) through each portion 320-b, each portion 330, and each portion 335 to expose the first semiconductor material 340 along a second side of the pillar 345 opposite the first side along the x-direction.

As a result of forming the voids 365, the portions 330 of the third dielectric material may be divided into dielectric portions 120-a at a third side of the pillar 345 along the y-direction and dielectric portions 120-b at a fourth side of the pillar 345 opposite the third side along the y-direction. Similarly, by forming the voids 365, the portions 335 of the storage material may be divided into ferroelectric portions 125-a (e.g., storage portions) at the third side of the pillar 345 and ferroelectric portions 125-b at the fourth side of the pillar 345.

The portions 320 of the first dielectric material may also be divided into multiple portions due to the formation of the voids 365. For example, the portion 320-b may be divided into the portion 370-a on a first side of the cavity 360-b along the y-direction and into the portion 370-b on a second side of the cavity 360-b opposite the first side along the y-direction. The portion 320-a may be divided into the portion 370-c on a first side of the cavity 360-a along the y-direction and into the portion 370-d on a second side of the cavity 360-a opposite the first side. As illustrated in the cross-sectional view E-E, the portions 320-b may be divided into the portions 370-a-1, 370-a-2, 370-b-1, and 370-b-2, and the portions 370 may each be positioned between respective oxide layers 310 and each be formed to be in contact with a respective word line 150.

FIG. 3D shows the architecture 300 (e.g., as an architecture 300-d) after a fourth set of one or more fabrication operations.

For example, after forming the voids 365-a, multiple portions 380-a of the second semiconductor material may be formed, such that each portion 380-a of the second semiconductor material is formed through a respective portion 330 of the first dielectric material and through a respective portion 335 of the storage material on the first side of the pillar 345 (e.g., and along a sidewall of the cavity 360-a). Additionally, after forming the voids 365-b, multiple portions 380-b of the second semiconductor material may be formed, such that each portion 380-b may be formed through a respective portion 330 of the first dielectric material and through a respective portion 335 of the storage material on the second side of the pillar 345 (e.g., and along a sidewall of the cavity 360-b). To form the portions 380-a along the first side of the pillar 345, the second semiconductor material may be formed in the cavity 360-a and into each respective void 365-a. Similarly, to form the portions 380-b along the second side of the pillar 345, the second semiconductor material may be formed in the cavity 360-b and into each respective void 365-b.

After forming the portions 380, a respective fifth cavity may be formed in the second semiconductor material (e.g., through the portions 380 of the second semiconductor material, along the z-direction). After forming the fifth cavities, access lines 160 may be formed in the fifth cavities (e.g., by forming one or more conductive materials in the fifth cavities). The access lines may extend along the z-direction through the stack of layers (e.g., terminating at or above the substrate). For example, a core conductor material (e.g., tungsten, molybdenum) may be deposited into the cavities, which may follow formation of a barrier material or omit formation of a barrier material, thereby forming the access lines 160, such as the bit line 160-a and the source line 160-b. In some examples, forming the access lines 160 may complete formation of at least a portion of the memory array (e.g., pillars 140 of an architecture 200).

FIG. 3E shows cross-sectional views of the architecture 300-d. As illustrated in the cross-sectional view F-F, the source line 160-b may extend, along the z-direction, through the stack of layers (e.g., terminating at or above the substrate). Additionally, the portion 380-b of the second semiconductor material may extend along a length of the source line 160-b along the z-direction, be continuous around the source line 160-b (e.g., in the xy-plane), and be in contact with each portion 370 of the first dielectric material (e.g., in the yz-plane). In such examples, the portions 370 may be recessed at each word line deck. For example, the portion 370-a-1 may be recessed into the word line 150-a-1 and be between the oxide layer 310-a and the oxide layer 310-b, and the portion 370-a-2 may be recessed into the word line 150-a-2 and be between the oxide layer 310-b and the oxide layer 310-c. Similarly, the portion 370-b-1 may be recessed into the word line 150-b-1 and be between the oxide layer 310-a and the oxide layer 310-b, and the portion 370-b-2 may be recessed into the word line 150-b-2 and be between the oxide layer 310-b and the oxide layer 310-c. In some other examples, the portions 370 may be formed to extend a length 376 in the y-direction at each word line 150 (e.g., fill the portions 325-a, as described with reference to FIG. 3A).

As illustrated in the cross-sectional view G-G, each ferroelectric portion 125 and dielectric portion 120 may be recessed into a respective word line and be between two respective oxide layers 310. For example, the first ferroelectric portion 125-a-1 and the dielectric portion 120-a-1 may be recessed into word line 150-a-1 and between the oxide layer 310-a and the oxide layer 310-b, and the first ferroelectric portion 125-a-2 and the dielectric portion 120-a-2 may be recessed into the word line 150-a-2 and between the oxide layer 310-b and the oxide layer 310-c. Similarly, the second ferroelectric portion 125-b-1 and the dielectric portion 120-b-1 may be recessed into word line 150-b-1 and between the oxide layer 310-a and the oxide layer 310-b, and the second ferroelectric portion 125-b-2 and the dielectric portion 120-b-2 may be recessed into the word line 150-b-2 and between the oxide layer 310-b and the oxide layer 310-c. Although illustrated as extending through the stack of materials, in some examples, the first semiconductor material 340 may be recessed at each word line deck (e.g., distinct portions along the z-direction, separated by oxide layers 310), such that each ferroelectric portion 125 may be coupled with a respective portion of the first semiconductor material 340.

Accordingly, to access a memory cell 105 that includes the dielectric portion 120-a-1 and the first ferroelectric portion 125-a-1, a voltage may be applied to the word line 150-a-1 (e.g., and across the dielectric portion 120-a-1 and the first ferroelectric portion 125-a-1), which may modulate conductivity of a channel, between the bit line 160-a and the source line 160-b-1, via the first semiconductor material 340, and the portions 380-a and 380-b of the second semiconductor material (e.g., at a side along the positive y-direction of the pillar 345, as described herein with reference to FIGS. 2A and 2B). Similarly, to access a memory cell 105 that includes the dielectric portion 120-b-1 and the first ferroelectric portion 125-b-1, a voltage may be applied to the word line 150-b-1 (e.g., and across the dielectric portion 120-b-1 and the first ferroelectric portion 125-b-1), which may modulate conductivity of a channel, between the bit line 160-a and the source line 160-b-1, via the first semiconductor material 340, and the portions 380-a and 380-b of the second semiconductor material (e.g., at a side along the negative y-direction of the pillar 345, as described herein with reference to FIGS. 2A and 2B).

As illustrated in the cross-sectional view H-H, the bit line 160-a and the source line 160-b may be in contact with portions 380 (e.g., portions 381, between oxide layers 310) of the second semiconductor material. For example, each respective portion 381 of the second semiconductor material may be formed into (e.g., overlap with, be associated with) a respective word line deck. Additionally, each respective portion 380 (e.g., portions 381) may be in contact with the first semiconductor material 340. For example, the source line 160-b may be in contact with the portion 380-b of the second semiconductor material, which may be continuous with the portion 381-b-1 (e.g., corresponding to the word line deck including the word line 150-a-1 and the word line 150-b-1) and the portion 381-b-2 (e.g., corresponding to the word line deck including the word line 150-a-2 and the word line 150-b-2). Similarly, the bit line 160-a may be in contact with the portion 380-a, which may be continuous with the portion 381-a-1 (e.g., corresponding to the word line deck including the word line 150-a-1 and the word line 150-b-1) and the portion 381-a-2 (e.g., corresponding to the word line deck including the word line 150-a-2 and the word line 150-b-2).

FIG. 3F shows the architecture 300. As described herein, the architecture 300 may include multiple pillars 345 formed into a stack of materials, which may include an alternation (e.g., along the z-direction) between word line decks (e.g., word lines 150) and oxide layers 310, such that each pillar 345 may be positioned between a respective source line 160-b (e.g., a conductive pillar) and a respective bit line 160-a (e.g., another conductive pillar pillar). Each pillar 345 may include a core dielectric material (e.g., silicon dioxide) that extends through the stack of materials along the z-direction, and a first semiconductor material 340 (e.g., one or more channel portions 130) around the core dielectric material that extends along the length of the pillar 345 along the z-direction.

As described herein with reference to FIG. 2B, the architecture 300 may include multiple word line decks, and each word line deck may include a single odd word line 150-a (e.g., a first conductor) and a single even word line 150-b (e.g., a second conductor, interleaved with the single odd word line 150-a) arranged in a comb-like structure. Such even and odd word lines 150 may be separated (e.g., isolated, along the x-direction) via dielectric structures 390. Further, a respective combination of pillars 345, bit lines 160-a, and source lines 160-b may be separated (e.g., isolated, along the x-direction) via a dielectric pillar 385, such that each bit line 160-a and each source line 160-b is coupled with a single pillar 345.

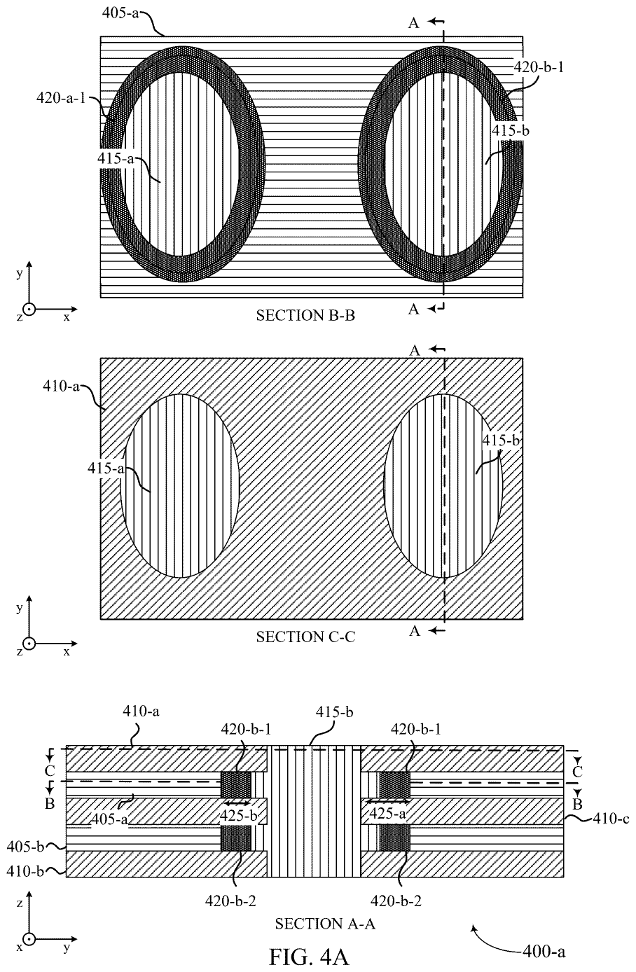

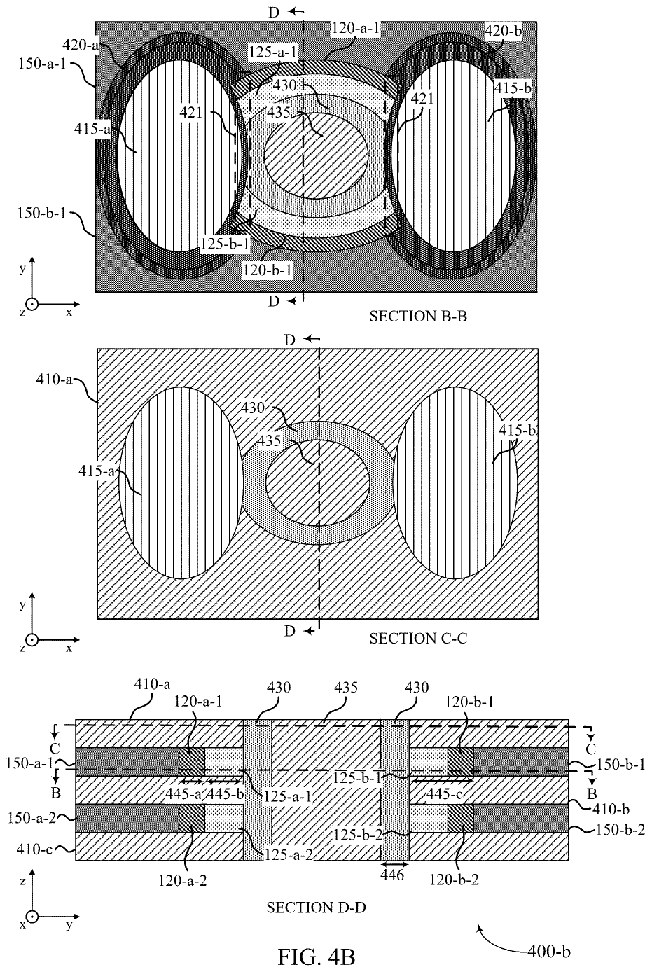

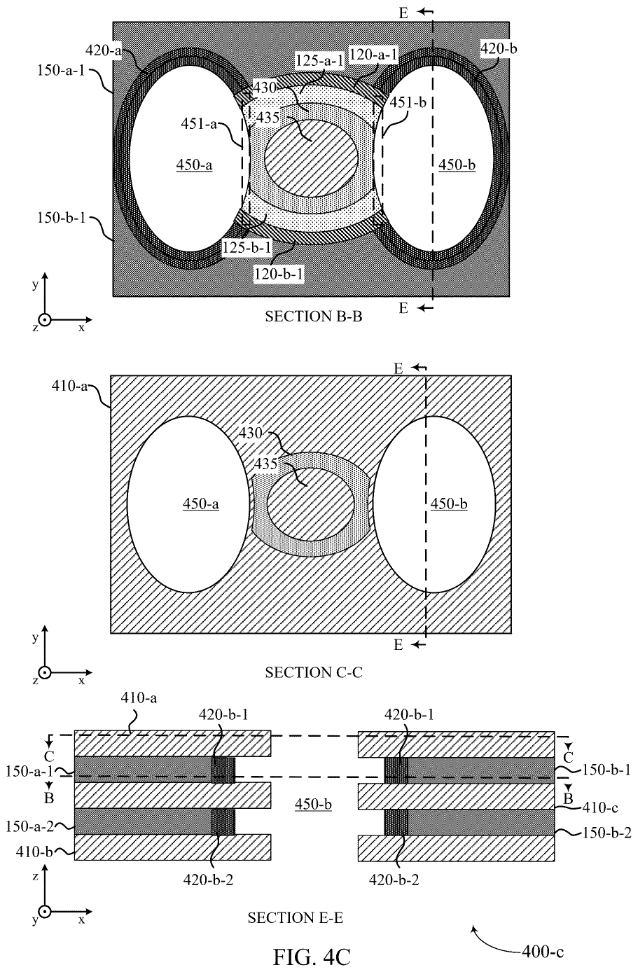

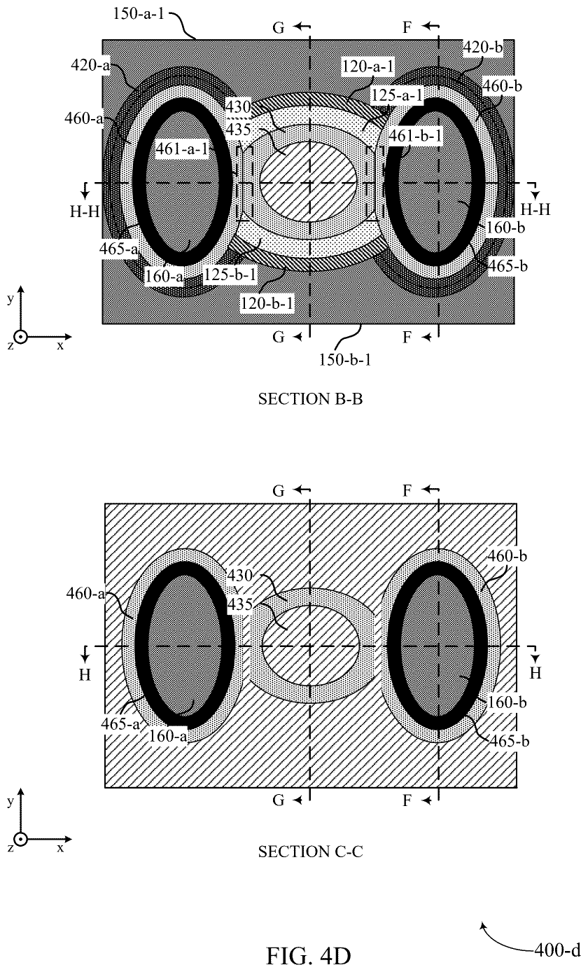

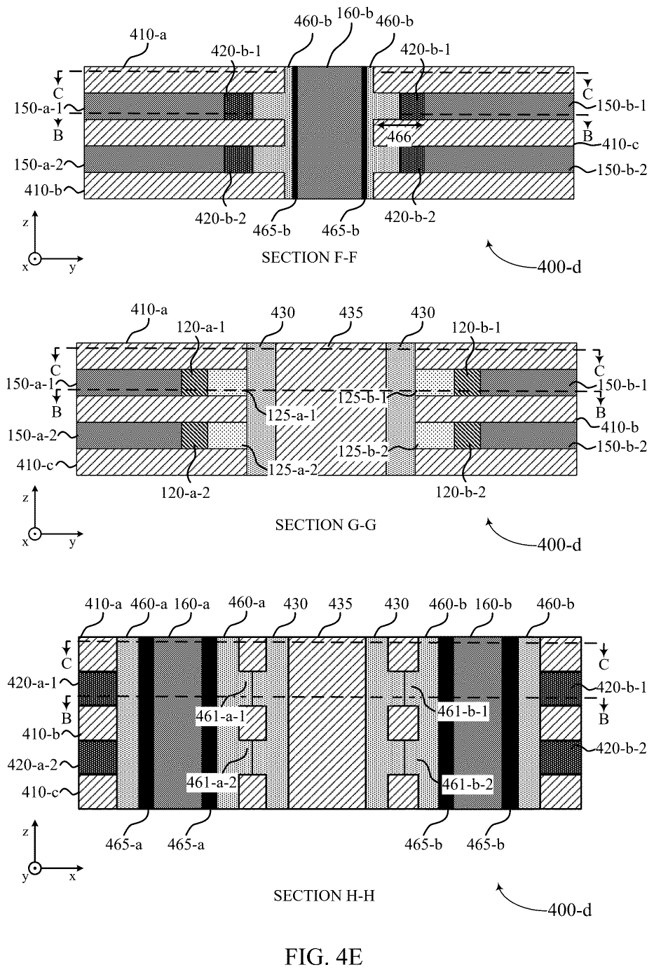

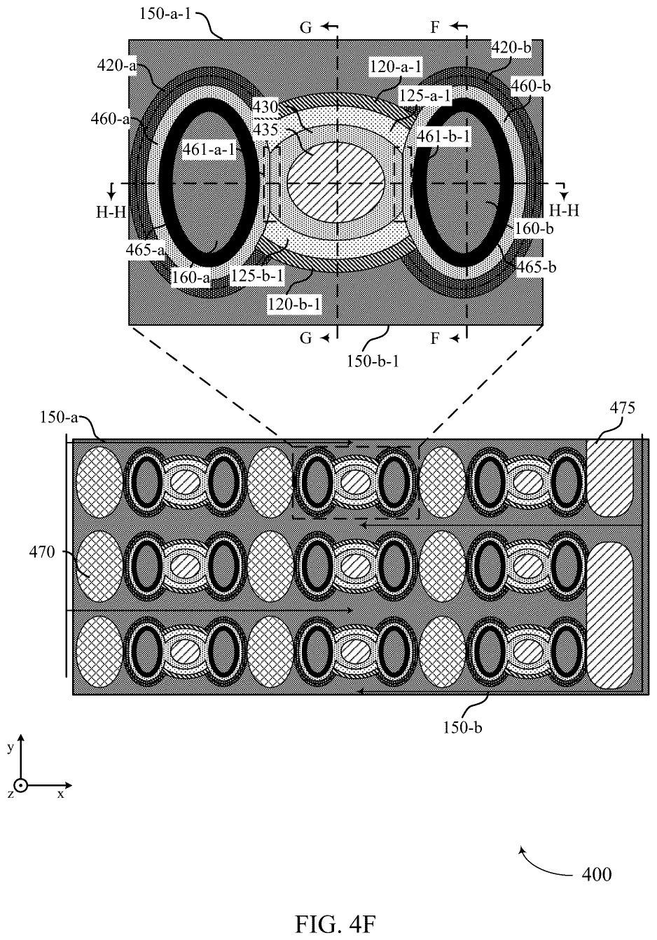

FIGS. 4A, 4B, 4C, 4D, 4E, and 4F show examples of fabrication operations that support FeNOR architectures in accordance with examples as disclosed herein. For example, FIGS. 4A through 4F may illustrate a sequence of operations for fabricating aspects of an architecture 400 (e.g., as a portion of a semiconductor wafer), which may implement aspects of a memory device 100, or an architecture 200, or another implementation of a semiconductor component (e.g., a memory component). In some examples, the architecture 400 may be a portion of memory die, or a wafer that includes multiple memory dies, such as NOR die (e.g., a 3D-NOR die, a die having an arrangement of NOR memory cells in a three-dimensional array). Although some elements included in FIGS. 4A through 4F are labeled with reference numbers, some other corresponding elements are not labeled, though they would be understood by a person having ordinary skill in the art to be the same as or similar to the labeled elements.

Each of FIGS. 4A through 4F may illustrate aspects of the architecture 400 after different subsets of the fabrication operations for forming the architecture 400 (e.g., illustrated as an architecture 400-a after a first set of one or more fabrication operations, as an architecture 400-b after a second set of one or more fabrication operations, and so on). Each view of FIGS. 4A through 4F may be described with reference to an x-direction (e.g., a first direction over a substrate, not shown), a y-direction (e.g., a second direction over the substrate), and a z-direction (e.g., a direction from the substrate) of the illustrated coordinate system, which may correspond to the respective directions described with reference to the architecture 200. Aspects of the architecture 400 may be illustrated in accordance with cross-sectional section views A-A (e.g., in a yz-plane), B-B (e.g., in an xy-plane), C-C (e.g., in an xy plane), D-D (e.g., in a yz-plane), E-E (e.g., in an xz-plane), F-F (e.g., in a yz-plane), G-G (e.g., in a yz plane), and H-H (e.g., in a xz-plane) to show embedded features of the architecture 400.

FIG. 4A shows the architecture 400 (e.g., as an architecture 400-a) after a first set of one or more fabrication operations.

For example, a stack of layers (e.g., layers in a respective xy-plane) may be formed over a substrate, and the stack of layers may include nitride layers 405 and oxide layers 410 that are alternating along the z-direction. As illustrated in the cross-sectional view A-A, the stack of layers may be formed to include oxide layers 410-a, 410-b, and 410-c, with a nitride layer 405-a between the oxide layers 410-a and 410-b and a nitride layer 405-b between the oxide layers 410-b and 410-c. An architecture 400 may include any quantity of nitride layers 405 and oxide layers 310, and a quantity of nitride layers 405 may, in some examples, correspond to a quantity of memory cells 105 in pillars 140 of a memory device 100. After forming the stack of layers, multiple cavities may be formed through the stack of layers along the z-direction (e.g., terminating at or above the substrate), which may be formed using an etching procedure (e.g., a dry etch, a directional etch, a laser material removal operation, among other examples). For example, a first cavity may be formed, corresponding to the pillar 415-a, and a second cavity may be formed, corresponding to the pillar 415-b. In such examples, the cavities may be formed in an elliptical shape (e.g., in the xy-plane), as illustrated in FIG. 4A. In some other examples, the cavities may be formed in an circular shape, a square shape, a rectangular shape, a rounded rectangular shape, or any combination thereof.

In some examples, one or more voids (e.g., third voids and fourth voids) may be formed in each nitride layer 405 of the stack of layers. For example, a procedure (e.g., nitride recess procedure) may be performed through each of the cavities (e.g., cavities associated with the pillars 415) to recess (e.g., remove) a respective portion 425-a of nitride from each nitride layer 405, thereby forming the one or more voids into each nitride layer 405 (e.g., between oxide layers 310). As illustrated in the cross-sectional view A-A, respective portions 425-a of the nitride layers 405-a and 405-b may be recessed, thereby forming a respective void (e.g., a fourth void).

After forming the one or more voids, a first dielectric material (e.g., silicon oxide (SiOx)) may be deposited into the cavities and into the voids. After depositing the first dielectric material into the cavities and the one or more voids, a portion of the first dielectric material may be removed (e.g., selectively etched) to reform the cavities (e.g., corresponding to the pillars 415), thereby forming the portions 420 into each void of the nitride layers 405. For example, respective portions 420-a of the first dielectric material may be formed into each void through a first cavity, and respective portions 420-b may be formed into each void through a second cavity. As illustrated in the cross-sectional view A-A, a portion 420-b-1 may be formed into the void of the nitride layer 405-a, and a portion 420-b-2 may be formed into the void of the nitride layer 405-b. In some examples, as illustrated, the portions 420 of the first dielectric material may be formed in a portion 425-b of the voids at each nitride layer 405. Alternatively, the portions 420 of the first dielectric material may be formed to fill the portion 425-a removed from each nitride layer 405. That is, the portions 420 may be formed to fill the voids at each word line deck.

After forming the portions 420 of the first dielectric material, the pillars 415 may be formed. For example, a sacrificial material (e.g., SiCN, SOD) may be formed into each cavity, thereby forming the pillars 415-a (e.g., a first pillar) and 415-b (e.g., a second pillar). As such, each portion 420 may be continuous (e.g., a ring) around the respective pillar 415.

FIG. 4B shows the architecture 400 (e.g., as an architecture 400-b) after a second set of one or more fabrication operations.

For example, multiple third cavities (e.g., third cavities corresponding to the pillar 435 and the first semiconductor material 430) may be formed through the stack of layers along the z-direction (e.g., terminating at or above the substrate). In such examples, each third cavity may be formed between a respective pillar 415-a and a respective pillar 415-b. As illustrated, the third cavities may be formed in an elliptical shape (e.g., in the xy-plane), however, such cavities may be formed in a circular shape, a square shape, a rectangular shape, a rounded rectangular shape, or any combination thereof. In some examples, during the formation of the third cavities, a portion 421 of each portion 420 of the first dielectric material may be removed (e.g., pillar oxide partial etch back).

As a result of forming the third cavities, the nitride layers 405 may be divided into a comb structure, with multiple first nitride layers 405 at a first side of the third cavities along the y-direction and multiple second nitride layers 405 at a second side of the third cavities opposite the first side along the y-direction. That is, by forming the third cavities, each nitride layer 405 may divided into a first nitride layer 405 and a second nitride layer 405.

After forming the third cavities (e.g., corresponding to the pillar 435 and the first semiconductor material 430), a second dielectric material (e.g., AlOx, HfOx, SIOC, SiCN, silicon dioxide, or a combination thereof) may be formed into each third cavity. Accordingly, a subset of the third cavities (e.g., cavities associated with the active pillars, pillars between a bit line 160-a and a source line 160-b) chosen to include memory cells 105 may undergo a dielectric exhume and cell integration process, and a remaining subset of third cavities may remain protected by a mask and not open for the exhume operation. That is, after forming the third cavities, the second dielectric material may be formed into each third cavity, thereby forming dielectric pillars (not shown). Subsequently, the second dielectric material deposited into the third cavities associated with an active pillar may be exhumed (e.g., removed), thereby re-exposing the corresponding third cavity.

In some examples, after exhuming the second dielectric material, multiple word lines 150-a (e.g., odd word lines, conductors, formed using tungsten, molybdenum, or ruthenium) may be formed in place of the multiple first nitride layers 405 and multiple word lines 150-b (e.g., even word lines, conductors, formed using tungsten, molybdenum, or ruthenium) may be formed in place of the multiple second nitride layers 405. For example, after exhuming the second dielectric material to reform the third cavities, multiple first voids may be formed, for example, by exhuming, through the reformed third cavities, the nitride material from each of the multiple first nitride layers 405. Similarly, multiple second voids may be formed by exhuming, through the reformed third cavities, the nitride material from each of the multiple second nitride layers 405. A respective word line 150-a of the multiple word lines 150-a may be formed into a respective first void of the multiple first voids, and a respective word line 150-b of the multiple word lines 150-b may be formed into a respective second void of the multiple second voids. As illustrated in the cross-sectional view D-D, the nitride layer 405-a may be replaced by the word line 150-a-1 and the word line 150-b-1, and the nitride layer 405-b may be replaced by the word line 150-a-2 and the word line 150-b-2.

After forming the word lines 150, a procedure (e.g., metal recession procedure) may be performed to recess (e.g., remove) a respective portion 445-c of metal from each word line 150, thereby forming multiple first voids into each word line 150-a and multiple second voids into each word line 150-b. For example, a respective first void may be formed into each word line 150-a through a first side of a respective third cavity, and a respective second void may be formed into each word line 150-b through a second side of a respective third cavity opposite the first side along the y-direction. That is, as illustrated in the cross-sectional view D-D, a portion 445-c of the word lines 150-a-1, 150-a-2, 150-b-1, and 150-b-2 may be recessed.

Subsequently, multiple dielectric portions 120-a (e.g., interlayer portions, a third dielectric material the same as or different than the first or second dielectric materials) may be formed into a respective portion 445-a of a respective first void, and multiple dielectric portions 120-b may be formed into a respective portion 445-a of a respective second void. To do so, a third dielectric material (e.g., interlayer) may be formed into each exposed third cavity and into each respective first void and respective second void. Subsequently, a portion of the third dielectric material may be exhumed to reform each third cavity and form the respective dielectric portions 120. By doing so, a respective dielectric portion 120 may be positioned (e.g., recessed or confined) between each oxide layer 410 and be in contact with a respective word line deck. In some other examples, the third dielectric may be selectively deposited into the portions 445-a, thereby forming the dielectric portions 120. That is, the third dielectric material may be selectively deposited into the portions 445-a of the first voids, thereby forming the dielectric portions 120-a. The third dielectric material also may be selectively deposited into the portions 445-a of the second voids, thereby forming the dielectric portions 120-b. For example, as illustrated in the cross-sectional view D-D, the dielectric portion 120-a-1 may be formed into the word line 150-a-1 and the dielectric portion 120-a-2 may be formed into the word line 150-a-2. Similarly, the dielectric portion 120-b-1 may be formed into the word line 150-b-1 and the dielectric portion 120-b-2 may be formed into the word line 150-b-2

After forming the dielectric portions 120, multiple ferroelectric portions 125 (e.g., portions of a storage material) may be formed into the portions 455-b of a respective void in the word lines 150. For example, a ferroelectric material may be formed into each exposed third cavity and into the portions 445-b of each first void and each second void. Subsequently, a portion of the ferroelectric material may be exhumed to reform each third cavity. By doing so, a respective ferroelectric portion 125 may be positioned (e.g., recessed or confined) between each oxide layer 410 and be in contact with a respective dielectric portion 120. In some other examples, the ferroelectric material may be selectively deposited into the portions 445-b, thereby forming the ferroelectric portions 125. That is, the ferroelectric material may be selectively deposited into the portions 445-b of the first voids, thereby forming the ferroelectric portions 125-a. The ferroelectric material also may be selectively deposited into the portions 445-b of the second voids, thereby forming the ferroelectric portions 125-b. For example, as illustrated in the cross-sectional view D-D, the ferroelectric portion 125-a-1 may be formed into the word line 150-a-1 and in contact with the dielectric portion 120-a-1, and the ferroelectric portion 125-a-2 may be formed into the word line 150-a-2 and be in contact with the dielectric portion 120-a-2. Similarly, the ferroelectric portion 125-b-1 may be formed into the word line 150-b-1 and in contact with the dielectric portion 120-b-1, and the ferroelectric portion 125-b-2 may be formed into the word line 150-b-2 and be in contact with the dielectric portion 120-b-2.

After forming ferroelectric portions 120, the first semiconductor material 430 (e.g., p-type doped polysilicon) may be formed (e.g., deposited) along a sidewall of each third cavity according to a selected thickness 446, where the first semiconductor material 430 may be in contact with each ferroelectric portion 125. Due to forming the first semiconductor material 430 along the sidewall of each third cavity, a respective fourth cavity may be formed. In some examples, an etching procedure may be performed to adjust (e.g., decrease) the thickness 446 of the first semiconductor material 430. Accordingly, a respective pillar 435 may be formed into each fourth cavity. For example, an oxide material (e.g., core dielectric material), which may be a same oxide material or different oxide material than the oxide material used to form the oxide layers 410, may be formed into the fourth cavities to form the pillars 435. As illustrated in the cross-sectional view D-D, the first semiconductor material 430 may extend along a length of the pillar 435 along the z-direction and be between the pillar 435 and the ferroelectric portions 125 along the y-direction.

FIG. 4C shows the architecture 400 (e.g., as an architecture 400-c) after a third set of one or more fabrication operations.

For example, one or more cavities 450 may be formed by removing (e.g., exhuming) the sacrificial material from each pillar 415. For example, a cavity 450-a may be formed by removing the sacrificial material of the pillar 415-a, and the cavity 450-b may be formed by removing the sacrificial material of the pillar 415-b. As part of forming the cavities 450, multiple first voids 451-a may be formed by removing a remaining portion of the portions 420, which may expose the first semiconductor material 440 along the first side of the pillar 435 along the x-direction. Similarly, multiple second voids 451-b may be formed by removing a remaining portion of the portion 420-b, which may expose the first semiconductor material 440 along a second side of the pillar 435 opposite the first side along the x-direction.

FIG. 4D shows the architecture 400 (e.g., as an architecture 400-d) after a fourth set of one or more fabrication operations.

For example, after forming the voids 451-a, multiple portions 460-a of the second semiconductor material (e.g., n-type doped polysilicon) may be formed in the cavities 450 (e.g., into voids 451, along sidewalls of the cavities 450). The formation of the second semiconductor material may include forming portions 461-a of the second semiconductor material into respective voids 451-a (e.g., in contact with exposed sidewalls of the first semiconductor material), and forming portions 461-b of the second semiconductor material into respective voids 451-b (e.g., in contact with exposed sidewalls of the first semiconductor material opposite the portions 461-a, along the x-direction).

After forming the portions 460, a respective fifth cavity may be formed in the second semiconductor material (e.g., through the portions 460 of the second semiconductor material, along the z-direction). After forming the fifth cavities, access lines 160 may be formed in the fifth cavities (e.g., by forming one or more conductive materials in the fifth cavities). The access lines may extend along the z-direction through the stack of layers (e.g., terminating at or above the substrate). For example, a barrier material 465 (e.g., titanium silicon (TiSi), tungsten nitride (WN), titanium nitride (TiN)) may be formed along the sidewalls of a respective fifth cavity. For example, a barrier material 465-a may be formed along a sidewall of a respective fifth cavity, such that the barrier material 465-a may be in contact with the portion 460-a. Similarly, a barrier material 465-b may be formed along a sidewall of a respective fifth cavity, such that the barrier material 465-b may be in contact with the portion 460-b. After forming the barrier materials 465, a core conductor material (e.g., tungsten, molybdenum) may be deposited into the cavities, thereby forming the access lines 160, such as the bit line 160-a and the source line 160-b. In some examples, forming the access lines 160 may complete formation of at least a portion of the memory array (e.g., pillars 140 of an architecture 200).

FIG. 4E shows cross-sectional views of the architecture 400-d. As illustrated in the cross-sectional view F-F, the source line 160-b may extend, along the z-direction, through the stack of layers (e.g., terminating at or above a substrate). Additionally, the portion 460-b of the second semiconductor material may extend along a length of the source line 160-b, be continuous around the source line 160-b, and be in contact with each portion 420 of the first dielectric material. Further, the barrier material 465-b may extend along a length of the source line 160-b and be continuous around the source line 160-b. In such examples, the portions 420 may be recessed at each word line deck (e.g., between oxide layers 410), as described herein with reference to FIG. 4C. In some other examples, the portions 420 may be formed to extend along a length 466 in the y-direction of each word line 150 (e.g., fill the portions 425-a, as described with reference to FIG. 4A).

As illustrated in cross-sectional view G-G, each ferroelectric portion 125 and dielectric portion 120 may be recessed into a respective word line and be between two respective oxide layers 410. For example, the first ferroelectric portion 125-a-1 and the dielectric portion 120-a-1 may be recessed into word line 150-a-1 and between the oxide layer 410-a and the oxide layer 410-b, and the first ferroelectric portion 125-a-2 and the dielectric portion 120-a-2 may be recessed into the word line 150-a-2 and between the oxide layer 410-b and the oxide layer 410-c. Similarly, the second ferroelectric portion 125-b-1 and the dielectric portion 120-b-1 may be recessed into word line 150-b-1 and between the oxide layer 410-a and the oxide layer 410-b, and the second ferroelectric portion 125-b-2 and the dielectric portion 120-b-2 may be recessed into the word line 150-b-2 and between the oxide layer 410-b and the oxide layer 410-c. Although illustrated as extending through the stack of materials, in some examples, the first semiconductor material 430 may be recessed at each word line deck, such that each ferroelectric portion 125 may be coupled with a respective portion of the first semiconductor material 430.

Accordingly, to access a memory cell 105 that includes the dielectric portion 120-a-1 and the first ferroelectric portion 125-a-1, a voltage may be applied to the word line 150-a-1 (e.g., and across the dielectric portion 120-a-1 and the first ferroelectric portion 125-a-1), which may modulate conductivity of a channel, between the bit line 160-a and the source line 160-b, via the first semiconductor material 430, and the portions 460-a (e.g., portion 461-a-1) and 460-b (e.g., portion 461-b-1) of the second semiconductor material (e.g., at a side along the positive y-direction of the pillar 345, as described herein with reference to FIGS. 2A and 2B). Similarly, to access a memory cell 105 that includes the dielectric portion 120-b-1 and the first ferroelectric portion 125-b-1, a voltage may be applied to the word line 150-b-1 (e.g., and across the dielectric portion 120-b-1 and the first ferroelectric portion 125-b-1), which may modulate conductivity of a channel, between the bit line 160-a and the source line 160-b, via the first semiconductor material 430, and the portions 460-a (e.g., portion 461-a-1) and 460-b (e.g., portion 461-b-1) of the second semiconductor material (e.g., at a side along the negative y-direction of the pillar 345, as described herein with reference to FIGS. 2A and 2B)

As illustrated in cross-sectional view H-H, the bit line 160-a and the source line 160-b may be in contact with the barrier material 465 that extends along a length of the bit line 160-a and source line 160-b. The barrier materials 465 may be in contact with portions 460 of the second semiconductor material, each extending along a length of the respective bit line 160-a and the source line 160-b. Each of the portions 460 may be in contact with (e.g., continuous with) respective portions 461 of the second semiconductor material. As illustrated, each portion 461 of the second semiconductor material may be recessed at (e.g., overlap with, be associated with) a respective word line deck and be in contact with the first semiconductor material 430. For example, the source line 160-b may be in contact with the barrier material 465-b. The barrier material 465-b may be in contact with the portion 460-b of the second semiconductor material, which may be in contact with both the portion 461-b-1 (e.g., corresponding to the word line deck including the word line 150-a-1 and the word line 150-b-1) and the portion 461-b-2 (e.g., corresponding to the word line deck including the word line 150-a-2 and the word line 150-b-2). Similarly, the bit line 160-a may be in contact with the barrier material 465-a. The barrier material 465-a may be in contact with the portion 460-a, which may be in contact with both the portion 460-a-1 (e.g., corresponding to the word line deck including the word line 150-a-1 and the word line 150-b-1) and the portion 461-a-2 (e.g., corresponding to the word line deck including the word line 150-a-2 and the word line 150-b-2).

FIG. 4F shows the architecture 400. As described herein, the architecture 400 may include multiple pillars 435 formed into a stack of materials, which may include an alternation (e.g., along the z-direction) between word line decks (e.g., word lines 150) and oxide layers 410, such that each pillar 435 may be positioned between a respective source line 160-b (e.g., a conductive pillar) and a respective bit line 160-a (e.g., another conductive pillar pillar). Each pillar 435 may include a core dielectric material (e.g., silicon dioxide) that extends through the stack of materials along the z-direction, and a first semiconductor material 430 (e.g., one or more channel portions 130) around the core dielectric material that extends along the length of the pillar 435 along the z-direction.

As described herein with reference to FIG. 2B, the architecture 400 may include multiple word line decks, and each word line deck may include a single odd word line 150-a (e.g., a first conductor) and a single even word line 150-b (e.g., a second conductor, interleaved with the single odd word line 150-a) arranged in a comb-like structure. Such even and odd word lines 150 may be separated (e.g., isolated, along the x-direction) via dielectric structures 475. Further, a respective combination of pillars 435, bit lines 160-a, and source lines 160-b may be separated (e.g., isolated, along the x-direction) via a dielectric pillar 470, such that each bit line 160-a and each source line 160-b is coupled with a single pillar 435.

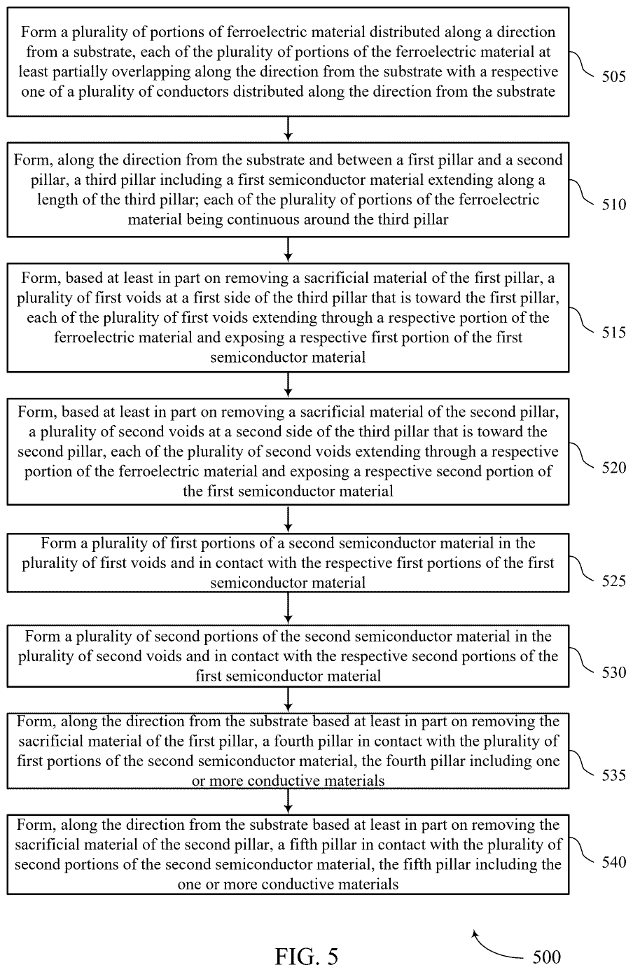

FIG. 5 shows a flowchart illustrating a method 500 that supports FeNOR memory architectures in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a plurality of portions of ferroelectric material distributed along a direction from a substrate, each of the plurality of portions of the ferroelectric material at least partially overlapping along the direction from the substrate with a respective one of a plurality of conductors distributed along the direction from the substrate.

At 510, the method may include forming, along the direction from the substrate and between a first pillar and a second pillar, a third pillar including a first semiconductor material extending along a length of the third pillar; each of the plurality of portions of the ferroelectric material being continuous around the third pillar.

At 515, the method may include forming, based at least in part on removing a sacrificial material of the first pillar, a plurality of first voids at a first side of the third pillar that is toward the first pillar, each of the plurality of first voids extending through a respective portion of the ferroelectric material and exposing a respective first portion of the first semiconductor material.

At 520, the method may include forming, based at least in part on removing a sacrificial material of the second pillar, a plurality of second voids at a second side of the third pillar that is toward the second pillar, each of the plurality of second voids extending through a respective portion of the ferroelectric material and exposing a respective second portion of the first semiconductor material.

At 525, the method may include forming a plurality of first portions of a second semiconductor material in the plurality of first voids and in contact with the respective first portions of the first semiconductor material.

At 530, the method may include forming a plurality of second portions of the second semiconductor material in the plurality of second voids and in contact with the respective second portions of the first semiconductor material.

At 535, the method may include forming along the direction from the substrate based at least in part on removing the sacrificial material of the first pillar, a fourth pillar in contact with the plurality of first portions of the second semiconductor material, the fourth pillar including one or more conductive materials.

At 540, the method may include forming along the direction from the substrate based at least in part on removing the sacrificial material of the second pillar, a fifth pillar in contact with the plurality of second portions of the second semiconductor material, the fifth pillar including the one or more conductive materials.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a plurality of portions of ferroelectric material distributed along a direction from a substrate, each of the plurality of portions of the ferroelectric material at least partially overlapping along the direction from the substrate with a respective one of a plurality of conductors distributed along the direction from the substrate; forming, along the direction from the substrate and between a first pillar and a second pillar, a third pillar including a first semiconductor material extending along a length of the third pillar; each of the plurality of portions of the ferroelectric material being continuous around the third pillar; forming, based at least in part on removing a sacrificial material of the first pillar, a plurality of first voids at a first side of the third pillar that is toward the first pillar, each of the plurality of first voids extending through a respective portion of the ferroelectric material and exposing a respective first portion of the first semiconductor material; forming, based at least in part on removing a sacrificial material of the second pillar, a plurality of second voids at a second side of the third pillar that is toward the second pillar, each of the plurality of second voids extending through a respective portion of the ferroelectric material and exposing a respective second portion of the first semiconductor material; forming a plurality of first portions of a second semiconductor material in the plurality of first voids and in contact with the respective first portions of the first semiconductor material; forming a plurality of second portions of the second semiconductor material in the plurality of second voids and in contact with the respective second portions of the first semiconductor material; forming, along the direction from the substrate based at least in part on removing the sacrificial material of the first pillar, a fourth pillar in contact with the plurality of first portions of the second semiconductor material, the fourth pillar including one or more conductive materials; and forming, along the direction from the substrate based at least in part on removing the sacrificial material of the second pillar, a fifth pillar in contact with the plurality of second portions of the second semiconductor material, the fifth pillar including the one or more conductive materials.

Aspect 2: The method or apparatus of aspect 1, where the plurality of conductors are positioned at a third side of the third pillar and the method, apparatuses, and non-transitory computer-readable medium further includes operations, features, circuitry, logic, means, or instructions, or any combination thereof for forming a plurality of second conductors distributed along the direction from the substrate, the plurality of second conductors positioned at a fourth side of the third pillar, opposite the third side of the third pillar.

Aspect 3: The method or apparatus of aspect 2, further including operations, features, circuitry, logic, means, or instructions, or any combination thereof for forming a stack of layers over the substrate, the stack of layers including a plurality of nitride layers alternating with a plurality of oxide layers; forming a first cavity and a second cavity along the direction from the substrate and through the stack of layers; forming, through the first cavity, a respective third void into each of the plurality of nitride layers based at least in part on recessing a first portion of each of the plurality of nitride layers; forming, through the second cavity, a respective fourth void into each of the plurality of nitride layers based at least in part on recessing a second portion of each of the plurality of nitride layers; forming, a respective first portion of a dielectric material in each of the respective third voids, where the first pillar is formed in the first cavity after on forming the respective first portions of the dielectric material, and where each of the respective first portions of the dielectric material is continuous around the first pillar; and forming, a respective second portion of the dielectric material in each of the respective fourth voids, where the second pillar is formed in the second cavity after forming the respective second portions of the dielectric material, and where each of the respective second portions of the dielectric material is continuous around the second pillar.

Aspect 4: The method or apparatus of aspect 3, further including operations, features, circuitry, logic, means, or instructions, or any combination thereof for forming, along the direction from the substrate and through the stack of layers, a third cavity between the first pillar and the second pillar, the third cavity dividing the plurality of nitride layers into a plurality of first nitride layer portions, at a first side of the first pillar and a first side of the second pillar, and a plurality of second nitride layer portions, at a second side of the first pillar and a second side of the second pillar; forming a plurality of fifth voids based at least in part on exhuming the plurality of first nitride layer portions, where each of the plurality of conductors is formed in a respective one of the plurality of fifth voids; and forming a plurality of sixth voids based at least in part on exhuming the plurality of second nitride layer portions, where each of the plurality of second conductors is formed in a respective one of the plurality of sixth voids.

Aspect 5: The method or apparatus of aspect 4, where the first pillar and the second pillar support the plurality of oxide layers after exhuming the plurality of first nitride layer portions and exhuming the plurality of second nitride layer portions.

Aspect 6: The method or apparatus of any of aspects 4 through 5, where the third cavity is formed into each of the respective first portions of the dielectric material and into each of the respective second portions of the dielectric material.

Aspect 7: The method or apparatus of any of aspects 4 through 6, further including operations, features, circuitry, logic, means, or instructions, or any combination thereof for forming, through the third cavity, a respective seventh void into each first conductor of the plurality of conductors; forming, through the third cavity, a respective eighth void into each second conductor of the plurality of second conductors; and forming, into each of the respective seventh voids and into each of the respective eighth voids, a respective portion of a second dielectric material in contact with the respective conductor.

Aspect 8: The method or apparatus of aspect 7, where each of the plurality of first voids is formed through a respective one the plurality of portions of the second dielectric material at the first side of the third pillar and each of the plurality of second voids is formed through a respective one the plurality of portions of the second dielectric material at the second side of the first pillar.

Aspect 9: The method or apparatus of any of aspects 7 through 8, where forming the plurality of portions of the ferroelectric material includes operations, features, circuitry, logic, means, or instructions, or any combination thereof for forming the ferroelectric material into the respective seventh voids and into the respective eighth voids.

Aspect 10: The method or apparatus of aspect 9, where forming the third pillar includes operations, features, circuitry, logic, means, or instructions, or any combination thereof for forming, into the third cavity, the first semiconductor material; forming a fourth cavity into the first semiconductor material; and forming, into the fourth cavity, a core dielectric material.

Aspect 11: The method or apparatus of any of aspects 3 through 10, further including operations, features, circuitry, logic, means, or instructions, or any combination thereof for forming a third cavity based at least in part on removing the sacrificial material of the first pillar, where the plurality of first voids are formed through the third cavity; forming a fourth cavity based at least in part on removing the sacrificial material of the second pillar, where the plurality of second voids are formed through the fourth cavity; forming the second semiconductor material along a sidewall of the third cavity and into each of the plurality of first voids, the second semiconductor material in each of the plurality of first voids corresponding to the plurality of first portions of the second semiconductor material; forming the second semiconductor material along a sidewall of the fourth cavity and into each of the plurality of second voids, the second semiconductor material in each of the plurality of second voids corresponding to the plurality of second portions of the second semiconductor material; forming a fifth cavity along the direction from the substrate into the second semiconductor material in the third cavity, where forming the fourth pillar includes forming the one or more conductive materials in the fifth cavity; and forming a sixth cavity along the direction from the substrate into the second semiconductor material in the fourth cavity, where forming the fifth pillar includes forming the one or more conductive materials in the sixth cavity.

Aspect 12: The method or apparatus of aspect 11, where forming the one or more conductive materials includes operations, features, circuitry, logic, means, or instructions, or any combination thereof for forming a barrier material along a sidewall of the respective cavity and forming a different conductive material in contact with the barrier material.

Aspect 13: The method or apparatus of any of aspects 1 through 12, where the first semiconductor material includes p-type doped polysilicon and the second semiconductor material includes n-type doped polysilicon.

Aspect 14: The method or apparatus of any of aspects 1 through 13, where the first semiconductor material and the second semiconductor material include a same polysilicon material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: A memory device, including: a plurality of portions of a first semiconductor material; a first activation line of a memory array being positioned along a first side of each of the plurality of portions of the first semiconductor material; a second activation line of the memory array being positioned along a second side of each of the plurality of portions of the first semiconductor material opposite the first side; a plurality of first portions of a ferroelectric material, each of the plurality of first portions of the ferroelectric material being positioned between the first activation line and a respective one of the plurality of portions of the first semiconductor material and being associated with a respective first memory cell of a plurality of first memory cells of the memory array; a plurality of second portions of the ferroelectric material, each of the plurality of second portions of the ferroelectric material being positioned between the second activation line and a respective one of the plurality of portions of the first semiconductor material and being associated with a respective second memory cell of a plurality of second memory cells of the memory array; a plurality of first portions of a second semiconductor material between the first activation line and the second activation line, each of the plurality of first portions of the second semiconductor material in contact with a respective one of the plurality of portions of the first semiconductor material; a plurality of second portions of the second semiconductor material between the first activation line and the second activation line, each of the plurality of second portions of the second semiconductor material in contact with a respective one of the plurality of portions of the first semiconductor material opposite from a respective one of the plurality of first portions of the second semiconductor material; a plurality of first access lines, each of the plurality of first access lines extending through a respective one of the plurality of first portions of the second semiconductor material; and a plurality of second access lines, each of the plurality of second access lines extending through a respective one of the plurality of second portions of the second semiconductor material.

Aspect 16: The memory device of aspect 15, where: each of the plurality of first memory cells is operable to store a respective logic state based at least in part on a dipole orientation stored in a respective first portion of the plurality of first portions of the ferroelectric material; and each of the plurality of second memory cells is operable to store a respective logic state based at least in part on a dipole orientation stored in a respective second portion of the plurality of second portions of the ferroelectric material.

Aspect 17: The memory device of any of aspects 15 through 16, where: each of the plurality of first portions of the second semiconductor material is continuous around the respective one the plurality of first access lines; and each of the plurality of second portions of the second semiconductor material is continuous around the respective one of the plurality of second access lines.

Aspect 18: The memory device of any of aspects 15 through 17, further including: a plurality of first portions of a barrier material, each of the plurality of first portions of the barrier material being positioned between a respective one of the plurality of first access lines and a respective one of the plurality of first portions of the second semiconductor material; and a plurality of second portions of the barrier material, each of the plurality of second portions of the barrier material being positioned between a respective one of the plurality of second access lines and a respective one of the plurality of second portions of the second semiconductor material.

Aspect 19: The memory device of aspect 18, where: each of the plurality of first portions of the barrier material is continuous around the respective one of the plurality of first access lines; and each of the plurality of second portions of the barrier material is continuous around the respective one of the plurality of second access lines.

Aspect 20: The memory device of any of aspects 15 through 19, further including: a plurality of first portions of a dielectric material, each of the plurality of first portions of the dielectric material positioned between the first activation line and a respective one of the plurality of first portions of the ferroelectric material; and a plurality of second portions of the dielectric material, each of the plurality of second portions of the dielectric material positioned between the second activation line and a respective one of the plurality of second portions of the ferroelectric material.

Aspect 21: The memory device of any of aspects 15 through 20, where the first semiconductor material includes p-type doped polysilicon and the second semiconductor material includes n-type doped polysilicon.

Aspect 22: The memory device of any of aspects 15 through 21, where each of the plurality of portions of the first semiconductor material is continuous around a dielectric core.

An apparatus is described. The following provides an overview of aspects of the apparatus as described herein:

Aspect 23: A memory device formed by a process, including: forming a plurality of portions of ferroelectric material distributed along a direction from a substrate, each of the plurality of portions of the ferroelectric material at least partially overlapping along the direction from the substrate with a respective one of a plurality of conductors distributed along the direction from the substrate; forming, along the direction from the substrate and between a first pillar and a second pillar, a third pillar including a first semiconductor material extending along a length of the third pillar; each of the plurality of portions of the ferroelectric material being continuous around the third pillar; forming, based at least in part on removing a sacrificial material of the first pillar, a plurality of first voids at a first side of the third pillar that is toward the first pillar, each of the plurality of first voids extending through a respective portion of the ferroelectric material and exposing a respective first portion of the first semiconductor material; forming, based at least in part on removing a sacrificial material of the second pillar, a plurality of second voids at a second side of the third pillar that is toward the second pillar, each of the plurality of second voids extending through a respective portion of the ferroelectric material and exposing a respective second portion of the first semiconductor material; forming a plurality of first portions of a second semiconductor material in the plurality of first voids and in contact with the respective first portions of the first semiconductor material; forming a plurality of second portions of the second semiconductor material in the plurality of second voids and in contact with the respective second portions of the first semiconductor material; forming, along the direction from the substrate based at least in part on removing the sacrificial material of the first pillar, a fourth pillar in contact with the plurality of first portions of the second semiconductor material, the fourth pillar including one or more conductive materials; and forming, along the direction from the substrate based at least in part on removing the sacrificial material of the second pillar, a fifth pillar in contact with the plurality of second portions of the second semiconductor material, the fifth pillar including the one or more conductive materials.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials, or combinations thereof. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a memory device, comprising:
forming a plurality of portions of ferroelectric material distributed along a direction from a substrate, each of the plurality of portions of the ferroelectric material at least partially overlapping along the direction from the substrate with a respective one of a plurality of conductors distributed along the direction from the substrate;
forming, along the direction from the substrate and between a first pillar and a second pillar, a third pillar comprising a first semiconductor material extending along a length of the third pillar; each of the plurality of portions of the ferroelectric material being continuous around the third pillar;
forming, based at least in part on removing a sacrificial material of the first pillar, a plurality of first voids at a first side of the third pillar that is toward the first pillar, each of the plurality of first voids extending through a respective portion of the ferroelectric material and exposing a respective first portion of the first semiconductor material;
forming, based at least in part on removing a sacrificial material of the second pillar, a plurality of second voids at a second side of the third pillar that is toward the second pillar, each of the plurality of second voids extending through a respective portion of the ferroelectric material and exposing a respective second portion of the first semiconductor material;
forming a plurality of first portions of a second semiconductor material in the plurality of first voids and in contact with the respective first portions of the first semiconductor material;
forming a plurality of second portions of the second semiconductor material in the plurality of second voids and in contact with the respective second portions of the first semiconductor material;
forming, along the direction from the substrate based at least in part on removing the sacrificial material of the first pillar, a fourth pillar in contact with the plurality of first portions of the second semiconductor material, the fourth pillar comprising one or more conductive materials; and
forming, along the direction from the substrate based at least in part on removing the sacrificial material of the second pillar, a fifth pillar in contact with the plurality of second portions of the second semiconductor material, the fifth pillar comprising the one or more conductive materials.

2. The method of claim 1, wherein the plurality of conductors are positioned at a third side of the third pillar, the method further comprising:
forming a plurality of second conductors distributed along the direction from the substrate, the plurality of second conductors positioned at a fourth side of the third pillar, opposite the third side of the third pillar.

3. The method of claim 2, further comprising:
forming a stack of layers over the substrate, the stack of layers comprising a plurality of nitride layers alternating with a plurality of oxide layers;
forming a first cavity and a second cavity along the direction from the substrate and through the stack of layers;
forming, through the first cavity, a respective third void into each of the plurality of nitride layers based at least in part on recessing a first portion of each of the plurality of nitride layers;
forming, through the second cavity, a respective fourth void into each of the plurality of nitride layers based at least in part on recessing a second portion of each of the plurality of nitride layers;
forming, a respective first portion of a dielectric material in each of the respective third voids, wherein the first pillar is formed in the first cavity after on forming the respective first portions of the dielectric material, and wherein each of the respective first portions of the dielectric material is continuous around the first pillar; and
forming, a respective second portion of the dielectric material in each of the respective fourth voids, wherein the second pillar is formed in the second cavity after forming the respective second portions of the dielectric material, and wherein each of the respective second portions of the dielectric material is continuous around the second pillar.

4. The method of claim 3, further comprising:
forming, along the direction from the substrate and through the stack of layers, a third cavity between the first pillar and the second pillar, the third cavity dividing the plurality of nitride layers into a plurality of first nitride layer portions, at a first side of the first pillar and a first side of the second pillar, and a plurality of second nitride layer portions, at a second side of the first pillar and a second side of the second pillar;
forming a plurality of fifth voids based at least in part on exhuming the plurality of first nitride layer portions, wherein each of the plurality of conductors is formed in a respective one of the plurality of fifth voids; and
forming a plurality of sixth voids based at least in part on exhuming the plurality of second nitride layer portions, wherein each of the plurality of second conductors is formed in a respective one of the plurality of sixth voids.

5. The method of claim 4, wherein the first pillar and the second pillar support the plurality of oxide layers after exhuming the plurality of first nitride layer portions and exhuming the plurality of second nitride layer portions.

6. The method of claim 4, wherein the third cavity is formed into each of the respective first portions of the dielectric material and into each of the respective second portions of the dielectric material.

7. The method of claim 4, further comprising:
forming, through the third cavity, a respective seventh void into each first conductor of the plurality of conductors;
forming, through the third cavity, a respective eighth void into each second conductor of the plurality of second conductors; and
forming, into each of the respective seventh voids and into each of the respective eighth voids, a respective portion of a second dielectric material in contact with the respective conductor.

8. The method of claim 7, wherein:
each of the plurality of first voids is formed through a respective one the plurality of portions of the second dielectric material at the first side of the third pillar; and
each of the plurality of second voids is formed through a respective one the plurality of portions of the second dielectric material at the second side of the first pillar.

9. The method of claim 7, wherein forming the plurality of portions of the ferroelectric material comprises:
forming the ferroelectric material into the respective seventh voids and into the respective eighth voids.

10. The method of claim 9, wherein forming the third pillar comprises:
forming, into the third cavity, the first semiconductor material;
forming a fourth cavity into the first semiconductor material; and
forming, into the fourth cavity, a core dielectric material.

11. The method of claim 3, further comprising:
forming a third cavity based at least in part on removing the sacrificial material of the first pillar, wherein the plurality of first voids are formed through the third cavity;
forming a fourth cavity based at least in part on removing the sacrificial material of the second pillar, wherein the plurality of second voids are formed through the fourth cavity;
forming the second semiconductor material along a sidewall of the third cavity and into each of the plurality of first voids, the second semiconductor material in each of the plurality of first voids corresponding to the plurality of first portions of the second semiconductor material;
forming the second semiconductor material along a sidewall of the fourth cavity and into each of the plurality of second voids, the second semiconductor material in each of the plurality of second voids corresponding to the plurality of second portions of the second semiconductor material;
forming a fifth cavity along the direction from the substrate into the second semiconductor material in the third cavity, wherein forming the fourth pillar comprises forming the one or more conductive materials in the fifth cavity; and
forming a sixth cavity along the direction from the substrate into the second semiconductor material in the fourth cavity, wherein forming the fifth pillar comprises forming the one or more conductive materials in the sixth cavity.

12. The method of claim 11, wherein forming the one or more conductive materials comprises:
forming a barrier material along a sidewall of the respective cavity; and
forming a different conductive material in contact with the barrier material.

13. The method of claim 1, wherein the first semiconductor material comprises p-type doped polysilicon and the second semiconductor material comprises n-type doped polysilicon.

14. The method of claim 1, wherein the first semiconductor material and the second semiconductor material comprise a same polysilicon material.

15. A memory device, comprising:
a plurality of portions of a first semiconductor material;
a first activation line of a memory array being positioned along a first side of each of the plurality of portions of the first semiconductor material;
a second activation line of the memory array being positioned along a second side of each of the plurality of portions of the first semiconductor material opposite the first side;
a plurality of first portions of a ferroelectric material, each of the plurality of first portions of the ferroelectric material being positioned between the first activation line and a respective one of the plurality of portions of the first semiconductor material and being associated with a respective first memory cell of a plurality of first memory cells of the memory array;
a plurality of second portions of the ferroelectric material, each of the plurality of second portions of the ferroelectric material being positioned between the second activation line and a respective one of the plurality of portions of the first semiconductor material and being associated with a respective second memory cell of a plurality of second memory cells of the memory array;
a plurality of first portions of a second semiconductor material between the first activation line and the second activation line, each of the plurality of first portions of the second semiconductor material in contact with a respective one of the plurality of portions of the first semiconductor material;
a plurality of second portions of the second semiconductor material between the first activation line and the second activation line, each of the plurality of second portions of the second semiconductor material in contact with a respective one of the plurality of portions of the first semiconductor material opposite from a respective one of the plurality of first portions of the second semiconductor material;
a plurality of first access lines, each of the plurality of first access lines extending through a respective one of the plurality of first portions of the second semiconductor material; and
a plurality of second access lines, each of the plurality of second access lines extending through a respective one of the plurality of second portions of the second semiconductor material.

16. The memory device of claim 15, wherein:
each of the plurality of first memory cells is operable to store a respective logic state based at least in part on a dipole orientation stored in a respective first portion of the plurality of first portions of the ferroelectric material; and
each of the plurality of second memory cells is operable to store a respective logic state based at least in part on a dipole orientation stored in a respective second portion of the plurality of second portions of the ferroelectric material.

17. The memory device of claim 15, wherein:
each of the plurality of first portions of the second semiconductor material is continuous around the respective one the plurality of first access lines; and
each of the plurality of second portions of the second semiconductor material is continuous around the respective one of the plurality of second access lines.

18. The memory device of claim 15, further comprising:
a plurality of first portions of a barrier material, each of the plurality of first portions of the barrier material being positioned between a respective one of the plurality of first access lines and a respective one of the plurality of first portions of the second semiconductor material; and
a plurality of second portions of the barrier material, each of the plurality of second portions of the barrier material being positioned between a respective one of the plurality of second access lines and a respective one of the plurality of second portions of the second semiconductor material.

19. The memory device of claim 18, wherein:
each of the plurality of first portions of the barrier material is continuous around the respective one of the plurality of first access lines; and
each of the plurality of second portions of the barrier material is continuous around the respective one of the plurality of second access lines.

20. The memory device of claim 15, further comprising:
a plurality of first portions of a dielectric material, each of the plurality of first portions of the dielectric material positioned between the first activation line and a respective one of the plurality of first portions of the ferroelectric material; and
a plurality of second portions of the dielectric material, each of the plurality of second portions of the dielectric material positioned between the second activation line and a respective one of the plurality of second portions of the ferroelectric material.

21. The memory device of claim 15, wherein the first semiconductor material comprises p-type doped polysilicon and the second semiconductor material comprises n-type doped polysilicon.

22. The memory device of claim 15, wherein each of the plurality of portions of the first semiconductor material is continuous around a dielectric core.

23. A memory device formed by a process, comprising:
forming a plurality of portions of ferroelectric material distributed along a direction from a substrate, each of the plurality of portions of the ferroelectric material at least partially overlapping along the direction from the substrate with a respective one of a plurality of conductors distributed along the direction from the substrate;
forming, along the direction from the substrate and between a first pillar and a second pillar, a third pillar comprising a first semiconductor material extending along a length of the third pillar; each of the plurality of portions of the ferroelectric material being continuous around the third pillar;
forming, based at least in part on removing a sacrificial material of the first pillar, a plurality of first voids at a first side of the third pillar that is toward the first pillar, each of the plurality of first voids extending through a respective portion of the ferroelectric material and exposing a respective first portion of the first semiconductor material;
forming, based at least in part on removing a sacrificial material of the second pillar, a plurality of second voids at a second side of the third pillar that is toward the second pillar, each of the plurality of second voids extending through a respective portion of the ferroelectric material and exposing a respective second portion of the first semiconductor material;
forming a plurality of first portions of a second semiconductor material in the plurality of first voids and in contact with the respective first portions of the first semiconductor material;
forming a plurality of second portions of the second semiconductor material in the plurality of second voids and in contact with the respective second portions of the first semiconductor material;
forming, along the direction from the substrate based at least in part on removing the sacrificial material of the first pillar, a fourth pillar in contact with the plurality of first portions of the second semiconductor material, the fourth pillar comprising one or more conductive materials; and
forming, along the direction from the substrate based at least in part on removing the sacrificial material of the second pillar, a fifth pillar in contact with the plurality of second portions of the second semiconductor material, the fifth pillar comprising the one or more conductive materials.
